(19) United States
(12) Patent Application Publication
(10) Pub. No.: US 2024/0147767 A1
(43) Pub. Date: May 2, 2024

(54) DISPLAY APPARATUS

(71) Applicant: Samsung Display Co., Ltd., Yongin-si (KR)

(72) Inventors: Seunglyong Bok, Yongin-si (KR); Haajin Yang, Yongin-si (KR)

(73) Assignee: Samsung Display Co., Ltd., Yongin-si (KR)

(21) Appl. No.: 18/326,229

(22) Filed: May 31, 2023

(30) Foreign Application Priority Data
Oct. 31, 2022 (KR) 10-2022-0143017

(51) Int. Cl. H10K 59/122; H10K 59/35

(52) U.S. Cl. CPC H10K 59/122; H10K 59/353

(57) ABSTRACT

A display apparatus includes a first pixel electrode, a second pixel electrode, and a third pixel electrode spaced apart from each other on a substrate, a pixel-defining layer including a first opening, a second opening, and a third opening, wherein the first opening exposes a central portion of the first pixel electrode, the second opening exposes a central portion of the second pixel electrode, and the third opening exposes a central portion of the third pixel electrode, wherein an area of the second opening is less than an area of the third opening, and a first distance between the first opening and the second opening is greater than a second distance between the first opening and the third opening.

### CROSS-REFERENCE TO RELATED APPLICATION

This application claims priority and benefits under 35 U.S.C. § 119 to Korean Patent Application No. 10-2022-0143017, filed on Oct. 31, 2022 in the Korean Intellectual Property Office, the disclosure of which is incorporated by reference herein in its entirety.

### BACKGROUND

### 1. Technical Field

The disclosure relates to a display apparatus with a reduced leakage current and improved display quality.

### 2. Description of the Related Art

Generally, display apparatuses include a display element, such as an organic light-emitting diode, and a thin-film transistor on a substrate, and operate by allowing display elements to emit light.

Specifically, each pixel of a display apparatus includes a display element, such as an organic light-emitting diode, wherein the organic light-emitting diode includes an intermediate layer between a pixel electrode and an opposite electrode, the intermediate layer including an emission layer. Generally, a display apparatus is configured to control whether each pixel emits light, or the intensity of the light emitted by the pixel, based on control of a thin-film transistor electrically connected to a pixel electrode. One or more layers of the intermediate layer of the display element are disposed in common on a plurality of display elements.

A display apparatus can encounter deterioration in color purity and/or display quality due to a leakage current. In case where a current is supplied to a display element of the display apparatus, the supplied current may form leakage current that is supplied to other adjacent display elements of the display apparatus through a layer that is disposed in common to the display elements: the supply of the leakage current to other adjacent display elements may cause a deterioration in color purity and/or display quality of the display apparatus.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

One or more embodiments include a display apparatus with a reduced leakage current and improved display quality. However, such a technical problem is an example, and the disclosure is not limited thereto.

Additional aspects will be set forth in part in the description which follows and, in part, will be apparent from the description, or may be learned by practice of the presented embodiments of the disclosure.

According to one or more embodiments, a display apparatus includes a first pixel electrode, a second pixel electrode, and a third pixel electrode spaced apart from each other on a substrate, a pixel-defining layer including a first opening, a second opening, and a third opening, wherein the first opening exposes a central portion of the first pixel electrode, the second opening exposes a central portion of the second pixel electrode, and the third opening exposes a central portion of the third pixel electrode, a first lower emission layer disposed on the first pixel electrode and configured to emit red light, a first upper emission layer disposed on the first lower emission layer and configured to emit red light, a second lower emission layer disposed on the second pixel electrode and configured to emit blue light, a second upper emission layer disposed on the second lower emission layer and configured to emit blue light, a third lower emission layer disposed on the third pixel electrode and configured to emit green light, a third upper emission layer disposed on the third lower emission layer and configured to emit green light, a first common layer disposed between the first pixel electrode and the first lower emission layer, between the second pixel electrode and the second lower emission layer, and between the third pixel electrode and the third lower emission layer, and further disposed on the first pixel electrode, the second pixel electrode, and the third pixel electrode, and an opposite electrode disposed on the first upper emission layer, the second upper emission layer, and the third upper emission layer, wherein an area of the second opening is less than an area of the third opening, and a first distance between the first opening and the second opening is greater than a second distance between the first opening and the third opening.

The display apparatus may further include at least one separator disposed on the pixel-defining layer, the at least one separator disposed between the first opening and the second opening, or the second opening and the third opening in a direction perpendicular to the substrate.

The at least one separator may include a plurality of separators, and the plurality of separators may be spaced apart from each other in the direction perpendicular to the substrate.

The at least one separator may include a reverse-tapered slope surface.

The at least one separator may extend along a side of the second opening.

A portion of the at least one separator may be disposed between the second opening and the third opening in the direction perpendicular to the substrate.

The display apparatus may further include a (1-1)st remaining common layer disposed on the at least one separator, and a first remaining opposite electrode disposed on the (1-1)st remaining common layer.

The (1-1)st remaining common layer and the first common layer may include a same material, and the first remaining opposite electrode and the opposite electrode may include a same material.

The display apparatus may further include at least one pixel-defining layer groove disposed in an upper surface of the pixel-defining layer, the at least one pixel-defining layer groove disposed between the first opening and the second opening, or between the second opening and the third opening in a direction perpendicular to the substrate.

The at least one pixel-defining layer groove may further include a plurality of pixel-defining layer grooves, and the plurality of pixel-defining layer grooves may be spaced apart from each other in the direction perpendicular to the substrate.

The at least one pixel-defining layer groove may include a forward-tapered slope surface.

The at least one pixel-defining layer groove may extend along a side of the second opening.

A portion of the at least one pixel-defining layer groove may be disposed between the second opening and the third opening in the direction perpendicular to the substrate.

The display apparatus may further include a spacer structure disposed on the pixel-defining layer, the spacer structure disposed between the first opening and the second opening, or the second opening and the third opening in a direction perpendicular to the substrate, wherein the spacer structure may include a plurality of sub-spacers.

The plurality of sub-spacers may be spaced apart from each other in the direction perpendicular to the substrate.

The plurality of sub-spacers may include reverse-tapered slope surfaces.

The display apparatus may further include a (1-2)nd remaining common layer disposed on the spacer structure, and a second remaining opposite electrode disposed on the (1-2)nd remaining common layer.

The (1-2)nd remaining common layer and the first common layer may include a same material, and the second remaining opposite electrode and the opposite electrode may include a same material.

The plurality of sub-spacers may include forward-tapered slope surfaces.

According to one or more embodiments, the display apparatus may further include a charge generation layer disposed between the first lower emission layer and the first upper emission layer, between the second lower emission layer and the second upper emission layer, and between the third lower emission layer and the third upper emission layer, a second common layer disposed between the first lower emission layer and the charge generation layer, between the second lower emission layer and the charge generation layer, and between the third lower emission layer and the charge generation layer, a third common layer disposed between the charge generation layer and the first upper emission layer, between the charge generation layer and the second upper emission layer, and between the charge generation layer and the third upper emission layer, and a fourth common layer disposed between the first upper emission layer and the opposite electrode, between the second upper emission layer and the opposite electrode, and between the third upper emission layer and the opposite electrode.

### BRIEF DESCRIPTION OF THE DRAWINGS

The above and other aspects and features of the disclosure will become more apparent by describing in detail embodiments thereof with reference to the attached drawings, in which:

FIG. 1 is a schematic plan view of a portion of a display apparatus according to an embodiment;

FIG. 2 is schematic diagram of an equivalent circuit of a pixel circuit electrically connected to a display element included in a pixel of the display apparatus of FIG. 1;

FIG. 3 is an enlarged schematic plan view of a region A of FIG. 1;

FIG. 4 is a schematic cross-sectional view of the display apparatus, taken along line I-I′ of FIG. 3;

FIG. 5 is a schematic view of a display apparatus according to an embodiment;

FIG. 6 is a view for explaining a size of an area of a second opening of a display apparatus according to an embodiment;

FIG. 7 is a schematic plan view of a portion of a display apparatus according to an embodiment;

FIG. 8 is a schematic cross-sectional view of the display apparatus, taken along line II-II of FIG. 7;

FIG. 9 is a schematic plan view of a portion of a display apparatus according to an embodiment;

FIG. 10 is a schematic plan view of a portion of a display apparatus according to an embodiment;

FIG. 11 is a schematic plan view of a portion of a display apparatus according to an embodiment;

FIG. 12 is a schematic plan view of a portion of a display apparatus according to an embodiment;

FIG. 13 is a schematic cross-sectional view of a display apparatus of FIG. 11, taken along line III-III′ of FIG. 12;

FIG. 14 is a schematic plan view of a portion of a display apparatus according to an embodiment;

FIG. 15 is a schematic cross-sectional view of a display apparatus of FIG. 11, taken along line IV-IV′ of FIG. 14;

FIG. 16 is a schematic cross-sectional view of a portion of a display apparatus according to an embodiment;

FIG. 17 is a schematic plan view of a portion of a display apparatus according to an embodiment;

FIG. 18 is a schematic plan view of a portion of a display apparatus according to an embodiment;

FIG. 19 is a schematic plan view of a portion of a display apparatus according to a comparative example;

FIG. 20 is a schematic plan view of a portion of a display apparatus according to an embodiment; and

FIG. 21 is a schematic plan view of a portion of a display apparatus according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

Reference will now be made in detail to embodiments, examples of which are illustrated in the accompanying drawings, wherein like reference numerals and/or reference characters refer to like elements throughout. In this regard, the embodiments may have different forms and should not be construed as being limited to the descriptions set forth herein. Accordingly, the embodiments are merely described below, by referring to the figures, to explain aspects of the description.

As the disclosure allows for various changes and numerous embodiments, certain embodiments will be illustrated in the drawings and described in the written description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described with reference to the accompanying drawings, wherein like reference numerals refer to like elements throughout and a repeated description thereof is omitted.

As used herein, when various elements such as a layer, a region, a plate, and the like are disposed “on” another element, not only the elements may be disposed “directly on” the other element, but another element may be disposed therebetween. In addition, sizes, thicknesses, ratios, and dimensions of elements in the drawings may be exaggerated or reduced for ease of description and for clarity.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

It will be understood that, although the terms first, second, etc., may be used herein to describe various elements, these elements should not be limited by these terms. These terms are only used to distinguish one element from another element. For example, a first element may be referred to as a second element, and similarly, a second element may be referred to as a first element without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned on, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “overlap”, “overlapping”, or “overlapped” mean that a first object may be above or below or to a side of a second object, and vice versa. Additionally, the term “overlap” may include layer, stack, face or facing, extending on, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as “not overlapping” or “to not overlap” another element, this may include that the elements are spaced apart from each other, offset from each other, or set aside from each other or any other suitable term as would be appreciated and understood by those of ordinary skill in the art.

The singular forms “a,” “an,” and “the” as used herein are intended to include the plural forms as well, unless the context clearly indicates otherwise.

The terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be understood that when an element (or a region, a layer, a portion, or the like) is referred to as “being on”, “disposed on”, “connected to” or “coupled to” another element in the specification, it can be directly disposed on, connected or coupled to another element mentioned above, or intervening elements may be disposed therebetween. It will be understood that the terms “connected to” or “coupled to” may include a physical or electrical connection or coupling.

In case that an element is referred to as being “in contact” or “contacted” or the like to another element, the element may be in “electrical contact” or in “physical contact” with another element; or in “indirect contact” or in “direct contact” with another element.

A description that a component is “configured to” perform a specified operation may be defined as a case where the component is constructed and arranged with structural features that can cause the component to perform the specified operation.

Embodiments may be described and illustrated in the accompanying drawings in terms of functional blocks, units, and/or modules.

Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies.

In the case of the blocks, units, and/or modules being implemented by microprocessors or other similar hardware, they may be programmed and controlled using software (for example, microcode) to perform various functions discussed herein and may optionally be driven by firmware and/or software.

It is also contemplated that each block, unit, and/or module may be implemented by dedicated hardware, or as a combination of dedicated hardware to perform some functions and a processor (for example, one or more programmed microprocessors and associated circuitry) to perform other functions.

Each block, unit, and/or module of embodiments may be physically separated into two or more interacting and discrete blocks, units, and/or modules without departing from the scope of the disclosure.

Further, the blocks, units, and/or modules of embodiments may be physically combined into more complex blocks, units, and/or modules without departing from the scope of the disclosure.

In the specification, a “distance between A and B” means a distance between a side of A nearest B and a side of B nearest A.

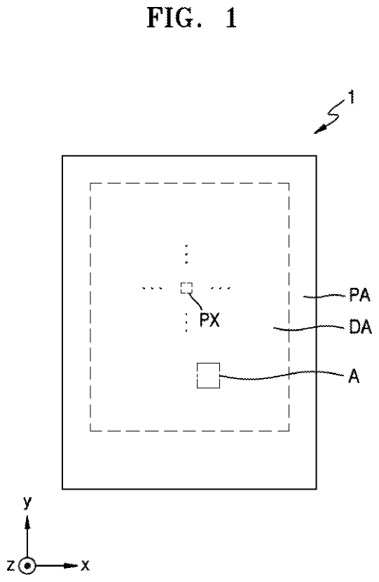

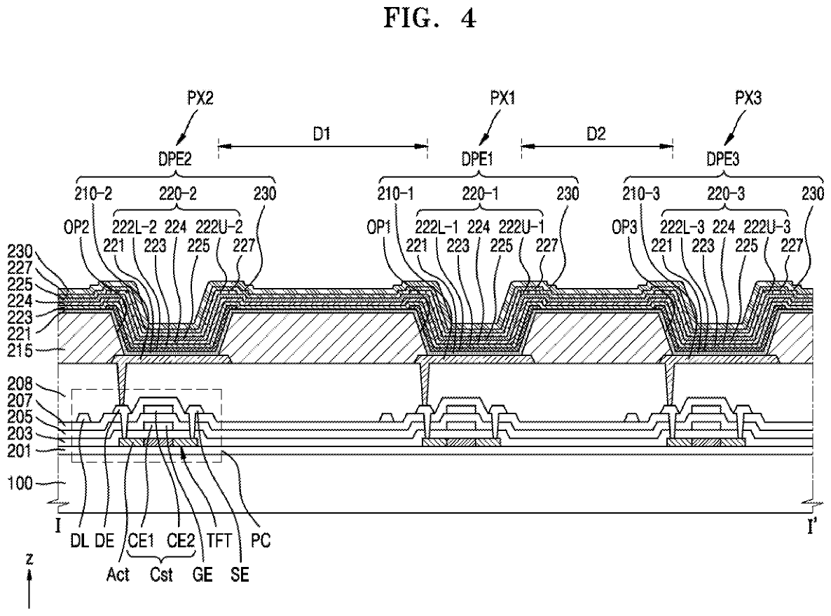

FIG. 1 is a schematic plan view of a display apparatus 1 according to an embodiment. As shown in FIG. 1, the display apparatus 1 may include a display area DA and a peripheral area PA, wherein pixels PX are disposed in the display area DA, and the peripheral area PA is outside the display area DA. Specifically, the peripheral area PA may surround the display area DA entirely. This may be understood that a substrate 100 (see FIG. 4) included in the display apparatus 1 includes the display area DA and the peripheral area PA.

Each pixel PX of the display apparatus 1 means a minimum part configured to display images, and the display apparatus 1 may be configured to display desired images through a combination of pixels PX. Specifically, each pixel PX may be configured to emit light of a preset color, and the display apparatus 1 may be configured to display desired images using light emitted from the pixels PX. As an example, each pixel PX may be configured to emit red light, green light, or blue light. Each pixel PX may include a display element, such as an organic light-emitting diode. The pixel PX may be electrically connected to a pixel circuit including a thin-film transistor TFT, a storage capacitor, and the like.

As shown in FIG. 1, the display area DA may have a polygonal shape including a quadrangular shape. As an example, the display area DA may have a rectangular shape in which a horizontal length thereof may be greater than a vertical length thereof, a rectangular shape in which a horizontal length thereof may be less than a vertical length thereof, or a square shape. As another example, the display area DA may have various shapes, such as an elliptical shape or a circular shape.

The peripheral area PA may be a non-display area in which the pixels PX are not present. A driver and the like configured to provide electric signals or power to the pixels PX may be disposed in the peripheral area PA. Pads (not shown) may be disposed in the peripheral area PA, wherein various kinds of electronic elements or a printed circuit board may be electrically connected to the pads. The pads may be spaced apart from each other in the peripheral area PA and electrically connected to a printed circuit board or an integrated circuit element.

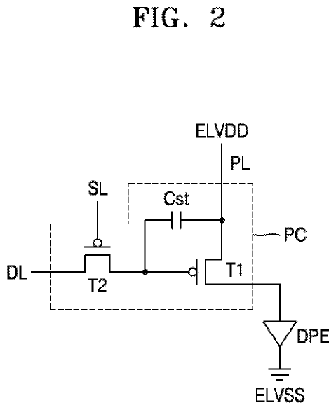

FIG. 2 is a schematic diagram of an equivalent circuit of a pixel circuit PC electrically connected to a display element DPE included in a pixel PX of the display apparatus 1 of FIG. 1.

The pixel circuit PC may include a first transistor T1, a second transistor T2, and a storage capacitor Cst. The second transistor T2 is a switching transistor and may be electrically connected to a scan line SL and a data line DL. The second transistor T2 may be configured to be activated in response to a switching signal, causing the second transistor T2 to transfer a data signal to the first transistor T1. The data signal may be an input from the data line DL, and the switching signal may be an input from the scan line SL. The storage capacitor Cst may include an end electrically connected to the second transistor T2, and another end electrically connected to a driving voltage line PL. The storage capacitor Cst is configured to store a voltage corresponding to a difference between a voltage transferred from the second transistor T2 and a driving power voltage ELVDD supplied to the driving voltage line PL.

The first transistor T1 is a driving transistor that may be electrically connected to the driving voltage line PL and the storage capacitor Cst, and may be configured to control the amount of driving current according to the voltage stored in the storage capacitor Cst, where the driving current flows from the driving voltage line PL to the display element DPE. The display element DPE may emit light having preset brightness based on the driving current. An opposite electrode of the display element DPE may receive an electrode power voltage ELVSS.

Though it is described with reference to FIG. 2 that the pixel circuit PC includes two transistors and a storage capacitor, the embodiment is not limited thereto. As an example, the number of transistors and the number of storage capacitors may be variously changed according to the design of the pixel circuit PC.

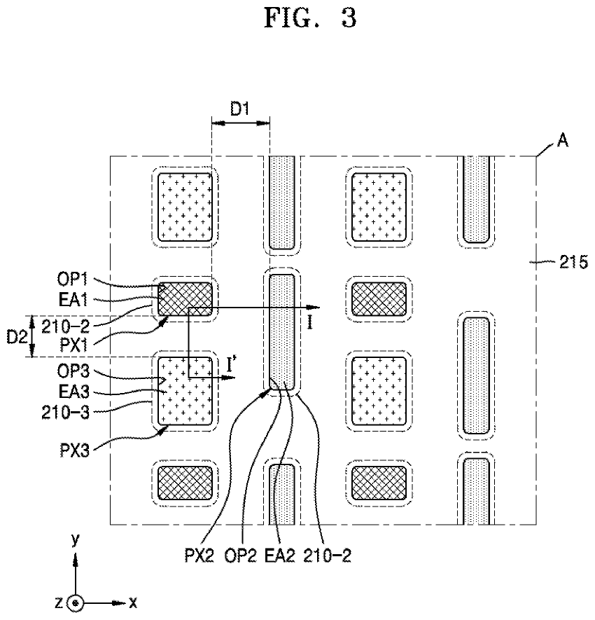

FIG. 3 is a schematic plan view of the display apparatus 1 according to an embodiment. Specifically, FIG. 3 is an enlarged schematic plan view of a region A of FIG. 1. For convenience of description, FIG. 3 shows a plan view of a pixel-defining layer 215.

As shown in FIG. 3, the display apparatus 1 may include the plurality of pixels PX. The plurality of pixels PX may include a first pixel PX1, a second pixel PX2, and a third pixel PX3. The first pixel PX1, the second pixel PX2, and the third pixel PX3 may be pixels configured to emit light of different colors. As an example, the first pixel PX1 may be a pixel configured to emit red light, the second pixel PX2 may be a pixel configured to emit blue light, and the third pixel PX3 may be a pixel configured to emit green light. Red light may be light in a wavelength band ranging from about 580 nm to about 780 nm, blue light may be light in a wavelength band ranging from about 400 nm to about 495 nm, and green light may be light in a wavelength band ranging from about 495 nm to about 580 nm.

The plurality of pixels PX may each include a display element DPE. The display element DPE may be a first display element DPE1 (see FIG. 4), a second display element DPE2 (see FIG. 4), or a third display element DPE3 (see FIG. 4). Specifically, the first pixel PX1 may include the first display element DPE1, the second pixel PX2 may include the second display element DPE2, and the third pixel PX3 may include the third display element DPE3. The display element DPE may include an intermediate layer disposed between a pixel electrode and an opposite electrode.

Accordingly, the first pixel PX1 may include a first pixel electrode 210-1, the second pixel PX2 may include a second pixel electrode 210-2, and the third pixel PX3 may include a third pixel electrode 210-3. The first pixel electrode 210-1, the second pixel electrode 210-2, and the third pixel electrode 210-3 may be spaced apart from each other on the substrate 100 (see FIG. 4). In the specification, the phrase “in a plan view” means viewing an object from the top in a z-axis direction perpendicular to the substrate 100. For example, “A and B apart from each other in a plan view” means “A and B apart from each other in a z-axis direction perpendicular to the substrate 100”. The phrase “in a schematic cross-sectional view” means viewing a cross-section in an x-axis direction or a y-axis direction of which the object is vertically cut from the side.

The pixel-defining layer 215 may be disposed on the first pixel electrode 210-1, the second pixel electrode 210-2, and the third pixel electrode 210-3, and may be disposed on the edges of each of the first pixel electrode 210-1, the second pixel electrode 210-2, and the third pixel electrode 210-3. For example, the pixel-defining layer 215 may include a first opening OP1, a second opening OP2, and a third opening OP3, wherein the first opening OP1 exposes a central portion of the first pixel electrode 210-1, the second opening OP2 exposes a central portion of the second pixel electrode 210-2, and the third opening OP3 exposes a central portion of the third pixel electrode 210-3.

Though not shown in FIG. 3, emission layers configured to emit light may be respectively disposed in the first opening OP1, the second opening OP2, and the third opening OP3 of the pixel-defining layer 215. The opposite electrodes may be disposed on the emission layers. As described above, a stack structure of the pixel electrode, the emission layer, and the opposite electrode may form a display element DPE. An opening of the pixel-defining layer 215 may correspond to a display element DPE and define an emission area.

As an example, an emission layer configured to emit red light may be disposed in the first opening OP1, and the first pixel PX1 may have a first emission area EA1 defined by the first opening OP1. Similarly, an emission layer configured to emit blue light may be disposed in the second opening OP2, and the second pixel PX2 may have a second emission area EA2 defined by the second opening OP2. Similarly, an emission layer configured to emit green light may be disposed in the third opening OP3, and the third pixel PX3 may have a third emission area EA3 defined by the third opening OP3.

For example, the first emission area EA1 may be defined by the first opening OP1, the second emission area EA2 may be defined by the second opening OP2, and the third emission area EA3 may be defined by the third opening OP3. Accordingly, the size of the area of the first opening OP1 may be the same as the size of the area of the first emission area EA1, the size of the area of the second opening OP2 may be the same as the size of the area of the second emission area EA2, and the size of the area of the third opening OP3 may be the same as the size of the area of the third emission area EA3. A distance between the first opening OP1 and the second opening OP2 may be the same as a distance between the first emission area EA1 and the second emission area EA2. A distance between the first opening OP1 and the third opening OP3 may be the same as a distance between the first emission area EA1 and the third emission area EA3, and a distance between the second opening OP2 and the third opening OP3 may be the same as a distance between the second emission area EA2 and the third emission area EA3.

The first opening OP1, the second opening OP2, and the third opening OP3 may each have a polygonal shape in a direction (a z-axis direction) perpendicular to the substrate 100. In other words, the first emission area EA1, the second emission area EA2, and the third emission area EA3 may each have a polygonal shape in a direction (the z-axis direction) perpendicular to the substrate 100. FIG. 3 illustrates that the first emission area EA1, the second emission area EA2, and the third emission area EA3 each have a quadrangular shape, specifically, a quadrangular shape having round edges viewed in the direction (the z-axis direction) perpendicular to the substrate 100. However, the embodiment is not limited thereto. As an example, the first emission area EA1, the second emission area EA2, and the third emission area EA3 may each have a circular shape or an elliptical shape in a direction (the z-axis direction) perpendicular to the substrate 100.

The first opening OP1, the second opening OP2, and the third opening OP3 may have areas of different sizes. Specifically, as shown in FIG. 3, the area of the second opening OP2 may be less than the area of the third opening OP3. The area of the first opening OP1 may be less than or equal to the area of the third opening OP3. In other words, the first emission area EA1, the second emission area EA2, and the third emission area EA3 may have areas of different sizes. Specifically, the area of the second emission area EA2 may be less than the area of the third emission area EA3. The area of the first emission area EA1 may be less than or equal to the area of the third emission area EA3. Detailed descriptions of the areas of the first opening OP1, the second opening OP2, and the third opening OP3 are made below.

Distances between the respective pixels PX may be different from each other. Specifically, the second pixel PX2 may be spaced apart from the first pixel PX1 by a first distance D1, and the third pixel PX3 may be spaced apart from the first pixel PX1 by a second distance D2. The first distance D1 may be greater than the second distance D2. For example, a distance between the first pixel PX1 and the second pixel PX2 may be the first distance D1, a distance between the first pixel PX1 and the third pixel PX3 may be the second distance D2, and the first distance D1 may be greater than the second distance D2.

In the specification, a distance between the pixels PX means a distance between emission areas of the pixels PX. In other words, a distance between the pixels PX means a distance between the openings defining the emission areas. Specifically, a distance between the pixels PX means a distance between a side of an opening and a side of another opening adjacent thereto. In other words, a distance between the pixels PX means a distance between a side of an emission area and a side of another adjacent emission area.

Accordingly, a “distance between the first pixel PX1 and the second pixel PX2” may be a distance between the first opening OP1 defining the first emission area EA1 and the second opening OP2 defining the second emission area EA2. Specifically, a distance between the first pixel PX1 and the second pixel PX2 is a distance between a side in a +x direction of the first opening OP1 and a side in an opposite −x direction of the second opening OP2. For example, a distance between the first opening OP1 and the second opening OP2 may be the first distance D1. A “distance between the first pixel PX1 and the third pixel PX3” may be a distance between the first opening OP1 defining the first emission area EA1 and the third opening OP3 defining the third emission area EA3. Specifically, a distance between the first pixel PX1 and the third pixel PX3 is a distance between a side in a −y direction of the first opening OP1 and a side in a +y direction of the third opening OP3. For example, a distance between the first opening OP1 and the third opening OP3 may be the second distance D2.

In other words, a “distance between the first pixel PX1 and the second pixel PX2” may be a distance between the first emission area EA1 and the second emission area EA2. Specifically, a distance between the first pixel PX1 and the second pixel PX2 is a distance between a side in the +x direction of the first emission area EA1 and a side in the −x direction of the second emission area EA2. For example, a distance between the first emission area EA1 and the second emission area EA2 may be the first distance D1. A distance between the first pixel PX1 and the third pixel PX3 may be a distance between the first emission area EA1 and the third emission area EA3. Specifically, a distance between the first pixel PX1 and the third pixel PX3 is a distance between a side in the −y direction of the first emission area EA1 and a side in the +y direction of the third emission area EA3. For example, a distance between the first emission area EA1 and the third emission area EA3 may be the second distance D2. A distance between the first pixel PX1 and the second pixel PX2 may be equal to or different from the first distance D1. The first distance D1 and the second distance D2 are described below in detail.

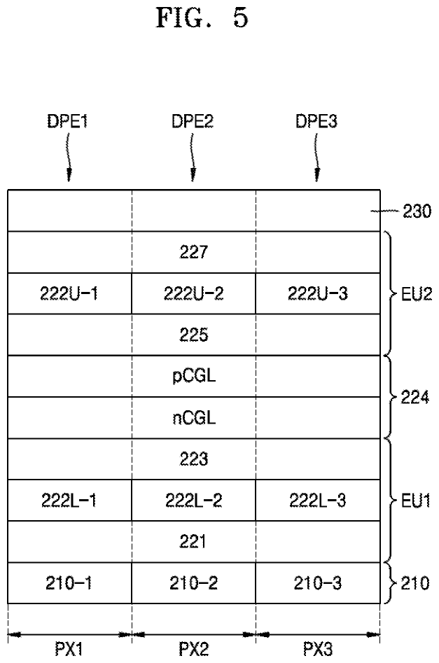

FIG. 4 is a schematic cross-sectional view of the display apparatus 1 according to an embodiment. Specifically, FIG. 4 is a schematic cross-sectional view of the display apparatus 1, taken along line I-I′ of FIG. 3. FIG. 5 is a schematic view of the display apparatus 1 according to an embodiment. Specifically, FIG. 5 is a schematic cross-sectional view of a stack structure of the display elements DPE in the pixels PX of the display apparatus 1 according to an embodiment.

As shown in FIG. 4, the display apparatus 1 according to an embodiment may include the substrate 100. The substrate 100 may include various flexible or bendable materials. As an example, the substrate 100 may include glass, metal, and/or polymer resin. In addition, the substrate 100 may include polymer resin, such as polyethersulphone, polyacrylate, polyetherimide, polyethylene naphthalate, polyethylene terephthalate, polyphenylene sulfide, polyarylate, polyimide, polycarbonate, cellulose acetate propionate, or a combination thereof. The substrate 100 may have a multi-layered structure including two layers each including the polymer resin, and a barrier layer including an inorganic material (such as silicon oxide, silicon nitride, and silicon oxynitride) therebetween. However, various modifications may be made.

The display element DPE and the pixel circuit PC may be disposed on the substrate 100. The pixel circuit PC may be electrically connected to the display element DPE. Specifically, the first pixel PX1, the second pixel PX2, and the third pixel PX3 may be disposed on the substrate 100. The first pixel PX1, the second pixel PX2, and the third pixel PX3 may each include the display element DPE. The display element DPE may be the first display element DPE1, the second display element DPE2, or the third display element DPE3. For example, the first pixel PX1 may include the first display element DPE1, the second pixel PX2 may include the second display element DPE2, and the third pixel PX3 may include the third display element DPE3.

The first display element DPE1, the second display element DPE2, and the third display element DPE3 are electrically connected to the pixel circuit PC, enabling the light emission to be controlled. The structures of the pixel circuits PC respectively electrically connected to the first display element DPE1, the second display element DPE2, and the third display element DPE3 may be substantially the same, hence a single pixel circuit PC can be described below. The pixel circuit PC includes thin-film transistors TFT and a storage capacitor Cst. For convenience of illustration, a thin-film transistor TFT is shown in FIG. 4. The thin-film transistor TFT may correspond to the driving thin-film transistor T1 (see FIG. 2).

A buffer layer 201 may be disposed between the first thin-film transistor TFT and the substrate 100, wherein the buffer layer 201 includes an inorganic material, such as silicon oxide, silicon nitride, and/or silicon oxynitride. The buffer layer 201 may increase flatness of the upper surface of the substrate 100, or prevent or reduce impurities from the substrate 100 penetrating a semiconductor layer Act of the thin-film transistor TFT.

As shown in FIG. 4, the thin-film transistor TFT may include the semiconductor layer Act including amorphous silicon, polycrystalline silicon, an organic semiconductor material, an oxide semiconductor material or a combination thereof. In addition, the thin-film transistor TFT may include a gate electrode GE, a source electrode SE, and/or a drain electrode DE. The gate electrode GE may include various conductive materials and have various layered structures, and include, for example, a Mo layer and/or an Al layer. As another example, the gate electrode GE may include a TiNₓ layer, an Al layer, and/or a Ti layer. The source electrode SE and the drain electrode DE may also include various conductive materials and various layered structures, and may include, for example, a Ti layer, an Al layer, and/or a Cu layer.

To secure insulation between the semiconductor layer Act and the gate electrode GE, a gate insulating layer 203 may be disposed between the semiconductor layer Act and the gate electrode GE, wherein the gate insulating layer 203 includes an inorganic material, such as silicon oxide, silicon nitride, and/or silicon oxynitride. Although it is shown in FIG. 4 that the gate insulating layer 203 has a shape corresponding to the entire surface of the substrate 100 and has a structure in which contact holes may be formed in preset portions, the embodiment is not limited thereto. As an example, the gate insulating layer 203 may be patterned to have the same shape as a shape of the gate electrode GE.

A first interlayer insulating layer 205 may be disposed on the gate electrode GE, wherein the first interlayer insulating layer 205 includes an inorganic material, such as silicon oxide, silicon nitride, and/or silicon oxynitride. The first interlayer insulating layer 205 may include a single-layered or multi-layered structure including the above materials. The insulating layer including the inorganic material may be formed by chemical vapor deposition (CVD) or atomic layer deposition (ALD). This is also applicable to embodiments below and modifications thereof.

The storage capacitor Cst may include a first electrode CE1 and a second electrode CE2 overlapping and facing each other in a plan view with the first interlayer insulating layer 205 between the first electrode CE1 and the second electrode CE2. The storage capacitor Cst may overlap and face the thin-film transistor TFT in a plan view. FIG. 4 illustrates that the gate electrode GE of the thin-film transistor TFT serves as the first electrode CE1 of the storage capacitor Cst, however the embodiment is not limited thereto. As an example, the storage capacitor Cst may not overlap the thin-film transistor TFT in a plan view. The second electrode CE2 of the storage capacitor Cst may include a conductive material including molybdenum (Mo), aluminum (Al), copper (Cu), and/or titanium (Ti) and have a single-layered or multi-layered structure including the above materials.

A second interlayer insulating layer 207 may be disposed on the second electrode CE2 of the storage capacitor Cst, wherein the second interlayer insulating layer 207 includes an inorganic material, such as silicon oxide, silicon nitride, and/or silicon oxynitride. The second interlayer insulating layer 207 may include a single-layered or multi-layered structure including the above materials.

The source electrode SE and the drain electrode DE may be disposed on the second interlayer insulating layer 207. The data line DL, the source electrode SE, and the drain electrode DE may be disposed on a same layer. The data line DL, the source electrode, SE and the drain electrode DE may include a same material. The source electrode SE, the drain electrode DE, and the data line DL may include a material having very high conductivity. The source electrode SE and the drain electrode DE may each include a conductive material including molybdenum (Mo), aluminum (Al), copper (Cu), and/or titanium (Ti) and include a single-layered or multi-layered structure including the above materials. As an example, the source electrode SE, the drain electrode DE, and the data line DL may have a multi-layered structure of Ti/Al/Ti.

However, the embodiment is not limited thereto. As an example, the thin-film transistor TFT may include a source electrode SE or a drain electrode DE, or may not include either the source electrode SE or the drain electrode DE. As an example, a thin-film transistor TFT may not include the drain electrode DE and another thin-film transistor TFT electrically connected to this thin-film transistor TFT may not include the source electrode SE, and the semiconductor layers Act of the two thin-film transistors may be electrically connected to each other. This connection structure may provide the same effect as an effect in which a thin-film transistor TFT includes the source electrode SE and another thin-film transistor TFT includes the drain electrode DE, and the source electrode SE of a thin-film transistor TFT may be electrically connected to the drain electrode DE of another thin-film transistor TFT.

As shown in FIG. 4, a planarization layer 208 may be disposed to cover the thin-film transistor TFT and the storage capacitor Cst. The planarization layer 208 may include an organic insulating material. As an example, the planarization layer 208 may include photoresist, benzocyclobutene (BCB), polyimide, hexamethyldisiloxane (HMDSO), polymethylmethacrylate (PMMA), polystyrene, polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, or a compound thereof, or a combination thereof. Though not shown in FIG. 4, a third interlayer insulating layer (not shown) may be further disposed under the planarization layer 208. The third interlayer insulating layer may include an inorganic insulating material, such as silicon oxide, silicon nitride, and/or silicon oxynitride.

The first display element DPE1, the second display element DPE2, and the third display element DPE3 may be spaced apart from each other on the planarization layer 208. Specifically, the first display element DPE1 and the second display element DPE2 adjacent to each other in a first direction (e.g., an x direction or a −x direction) may be disposed on the planarization layer 208, and the third display element DPE3 may be disposed in a second direction (e.g., a y direction or a −y direction) crossing the first direction (e.g., the x direction or the opposite −x direction) on the planarization layer 208 to be adjacent to the first display element DPE1. The first display element DPE1, the second display element DPE2, and the third display element DPE3 may be configured to emit light of different colors. As an example, the first display element DPE1 may be configured to emit red light, the second display element DPE2 may be configured to emit blue light, and the third display element DPE3 may be configured to emit green light.

The first display element DPE1 may include a first pixel electrode 210-1, a first intermediate layer 220-1, and an opposite electrode 230. The second display element DPE2 may include a second pixel electrode 210-2, a second intermediate layer 220-2, and the opposite electrode 230. The third display element DPE3 may include a third pixel electrode 210-3, a third intermediate layer 220-3, and the opposite electrode 230. For example, the first pixel electrode 210-1 of the first display element DPE1, the second pixel electrode 210-2 of the second display element DPE2, and the third pixel electrode 210-3 of the third display element DPE3 may be patterned for each pixel. The opposite electrode 230 of the first display element DPE1, the second display element DPE2, and the third display element DPE3 may be implemented as a structure on the first display element DPE1, the second display element DPE2, and the third display element DPE3. The first intermediate layer 220-1, the second intermediate layer 220-2, and the third intermediate layer 220-3 may be respectively disposed between the first pixel electrode 210-1, the second pixel electrode 210-2, and the third pixel electrode 210-3, and the opposite electrode 230.

The first pixel electrode 210-1, the second pixel electrode 210-2, and the third pixel electrode 210-3 may be spaced apart from each other on the substrate 100. Specifically, the first pixel electrode 210-1 and the second pixel electrode 210-2 may be spaced apart from each other on the planarization layer 208. As an example, the second pixel electrode 210-2 may be disposed adjacent to the first pixel electrode 210-1 in the first direction (e.g., the x direction or the opposite −x direction) on the planarization layer 208. The third pixel electrode 210-3 may be spaced apart from the first pixel electrode 210-1 on the planarization layer 208. As an example, the third pixel electrode 210-3 may be disposed adjacent to the first pixel electrode 210-1 in the second direction (e.g., the y direction or the opposite −y direction) on the planarization layer 208.

The first pixel electrode 210-1, the second pixel electrode 210-2, and the third pixel electrode 210-3 each may include a light-transmissive conductive layer and a reflective layer, wherein the light-transmissive conductive layer may include a light-transmissive conductive oxide, such as indium tin oxide (ITO), indium oxide (In₂O₃), and/or indium zinc oxide (IZO), and the reflective layer may include metal, such as aluminum (Al) or silver (Ag). As an example, the first pixel electrode 210-1, the second pixel electrode 210-2, and the third pixel electrode 210-3 may have a three-layered structure of ITO/Ag/ITO.

As shown in FIG. 4, the first pixel electrode 210-1, the second pixel electrode 210-2, and the third pixel electrode 210-3 may be electrically connected to the thin-film transistor TFT by contacting a source electrode SE or a drain electrode DE. Specifically, the first pixel electrode 210-1, the second pixel electrode 210-2, and the third pixel electrode 210-3 may each contact a source electrode SE or a drain electrode DE through a contact hole formed in the planarization layer 208.

The pixel-defining layer 215 may be disposed on the planarization layer 208. The pixel-defining layer 215 defines the pixel PX by including an opening corresponding to the pixel PX, for example, an opening exposing at least a central portion of the pixel electrode. Specifically, the pixel-defining layer 215 may include the first opening OP1, the second opening OP2, and the third opening OP3. The first opening OP1 may expose the central portion of the first pixel electrode 210-1, the second opening OP2 may expose the central portion of the second pixel electrode 210-2, and the third opening OP3 may expose the central portion of the third pixel electrode 210-3. In addition, in the case shown in FIG. 4, the pixel-defining layer 215 may increase a distance between the edge of the first pixel electrode 210-1 and the opposite electrode 230 on the first pixel electrode 210-1. Similarly, the pixel-defining layer 215 may increase a distance between the edge of the second pixel electrode 210-2 and the opposite electrode 230 and increase a distance between the edge of the third pixel electrode 210-3 and the opposite electrode 230. Accordingly, arcs and the like may be prevented from occurring at the edge of first pixel electrode 210-1, the edge of second pixel electrode 210-2, or the edge of third pixel electrode 210-3. The pixel-defining layer 215 may include an organic material, such as polyimide or HMDSO.

The opposite electrode 230 may be disposed on the first pixel electrode 210-1. The opposite electrode 230 may be implemented as a structure on the first display element DPE1, the second display element DPE2, and the third display element DPE3. Accordingly, the opposite electrode 230 may be also disposed on the second pixel electrode 210-2 and the third pixel electrode 210-3. The opposite electrode 230 may include a light-transmissive conductive layer including ITO, In₂O₃, and/or IZO, and include a semi-transmissive layer including metal, such as aluminum (Al) and/or silver (Ag). As an example, the opposite electrode 230 may be a semi-transmissive layer including magnesium (Mg) and silver (Ag).

The first intermediate layer 220-1 may be disposed between the first pixel electrode 210-1 and the opposite electrode 230. The second intermediate layer 220-2 may be disposed between the second pixel electrode 210-2 and the opposite electrode 230, and the third intermediate layer 220-3 may be disposed between the third pixel electrode 210-3 and the opposite electrode 230. For example, the first intermediate layer 220-1 may be disposed on the first pixel electrode 210-1, the second intermediate layer 220-2 may be disposed on the second pixel electrode 210-2, and the third intermediate layer 220-3 may be disposed on the third pixel electrode 210-3.

As shown in FIG. 5, the first display element DPE1, the second display element DPE2, and the third display element DPE3 may each have a tandem structure including emission layers. The first display element DPE1, the second display element DPE2, and the third display element DPE3 may each improve color purity and a light-emission efficiency by having a structure in which the emission layers are stacked each other.

In an embodiment, the first intermediate layer 220-1, the second intermediate layer 220-2, and the third intermediate layer 220-3 included in the display element DPE may each include the emission layers. Specifically, the first intermediate layer 220-1 may include a first lower emission layer 222L-1 and a first upper emission layer 222U-1. The first lower emission layer 222L-1 may be disposed on the first pixel electrode 210-1, and the first upper emission layer 222U-1 may be disposed on the first lower emission layer 222L-1 to overlap and face the first lower emission layer 222L-1 in a plan view. Similarly, the second intermediate layer 220-2 may include a second lower emission layer 222L-2 and a second upper emission layer 222U-2. The second lower emission layer 222L-2 may be disposed on the second pixel electrode 210-2, and the second upper emission layer 222U-2 may be disposed on the second lower emission layer 222L-2 to overlap and face the second lower emission layer 222L-2 in a plan view. Similarly, the third intermediate layer 220-3 may include a third lower emission layer 222L-3 and a third upper emission layer 222U-3. The third lower emission layer 222L-3 may be disposed on the third pixel electrode 210-3, and the third upper emission layer 222U-3 may be disposed on the third lower emission layer 222L-3 to overlap and face the third lower emission layer 222L-3 in a plan view.

The first lower emission layer 222L-1, the second lower emission layer 222L-2, and the third lower emission layer 222L-3 may be respectively patterned and individually implemented as part of the first display element DPE1, the second display element DPE2, and the third display element DPE3. In addition, the first upper emission layer 222U-1, the second upper emission layer 222U-2, and the third upper emission layer 222U-3 may be respectively patterned and individually implemented as part of the first display element DPE1, the second display element DPE2, and the third display element DPE3.

The first display element DPE1 may be configured to emit red light, the second display element DPE2 may be configured to emit blue light, and the third display element DPE3 may be configured to emit green light. The first lower emission layer 222L-1 and the first upper emission layer 222U-1 may be configured to emit red light, the second lower emission layer 222L-2 and the second upper emission layer 222U-2 may be configured to emit blue light, and the third lower emission layer 222L-3 and the third upper emission layer 222U-3 may be configured to emit green light. The first lower emission layer 222L-1, the second lower emission layer 222L-2, and the third lower emission layer 222L-3 may constitute a first emission part EU1, and the first upper emission layer 222U-1, the second upper emission layer 222U-2, and the third upper emission layer 222U-3 may constitute a second emission part EU2.

In an embodiment, a charge generation layer 224 may be disposed between the first lower emission layer 222L-1 and the first upper emission layer 222U-1, between the second lower emission layer 222L-2 and the second upper emission layer 222U-2, and between the third lower emission layer 222L-3 and the third upper emission layer 222U-3. The charge generation layer 224 may be implemented in common on the first display element DPE1, the second display element DPE2, and the third display element DPE3. The charge generation layer 224 may be configured to supply charge to the first emission part EU1 and the second emission part EU2, wherein the first emission part EU1 includes the first lower emission layer 222L-1, the second lower emission layer 222L-2, and the third lower emission layer 222L-3, and the second emission part EU2 includes the first upper emission layer 222U-1, the second upper emission layer 222U-2, and the third upper emission layer 222U-3. Accordingly, the light-emission efficiency of each of the first display element DPE1, the second display element DPE2, and the third display element DPE3 having the structure in which the emission layers are stacked each other may be further increased.

The charge generation layer 224 may include an n-type charge generation layer nCGL configured to supply electrons to the first emission part EU1, and a p-type charge generation layer pCGL configured to supply holes to the second emission part EU2.

The n-type charge generation layer nCGL may include an n-type dopant material and an n-type host material. The n-type dopant material may be a metal of Group 1 or Group 2 in the periodic table, an organic material capable of injecting electrons, or a mixture thereof. As an example, the n-type dopant material may be an alkali metal or an alkali earth metal. For example, although the n-type charge generation layer nCGL may include an organic layer doped with an alkali metal, such as lithium (Li), sodium (Na), potassium (K), and/or cesium (Cs), or an alkali earth metal, such as magnesium (Mg), strontium (Sr), barium (B a), and radium (Ra), the embodiment is not limited thereto. Although the n-type host material may include a material configured to transfer electrons, for example, at least one of Alq₃ (tris(8-hydroxyquinolino)aluminum), Liq (8-hydroxyquinolinolato-lithium), PBD (2-(4-biphenylyl)-5-(4-tert-butylphenyl)-1,3,4oxadiazole), TAZ (3-(4-biphenyl)4-phenyl-5-tert-butylphenyl-1,2,4-triazole), spiro-PBD, BAlq (bis(2-methyl-8-quinolinolate)-4-(phenylphenolato)aluminium), SAlq, TPBi(2,2′,2-(1,3,5-benzenetriyl)-tris(1-phenyl-1-H-benzimidazole), oxadiazole, triazole, phenanthroline, benzoxazole, and/or benzthiazole, or a combination thereof, the embodiment is not limited thereto.

The p-type charge generation layer pCGL may include a p-type dopant material and a p-type host material. Although the p-type dopant material may include a metal oxide, an organic material, such as tetrafluoro-tetracyanoquinodimethane (F4-TCNQ), an organic material, such as HAT-CN (hexaazatriphenylene-hexacarbonitrile), and/or hexaazatriphenylene, and/or metal such as V₂O₅, MoOₓ, and WO₃, the embodiment is not limited thereto. The p-type host material may include a material configured to transfer holes, for example, a material including at least one of NPD (N,N-dinaphthyl-N,N′-diphenyl benzidine) (N, N′-bis(naphthalene-1-yl)-N,N′-bis(phenyl)-2,T-dimethylbenzidine), TPD(N,N′-bis-(3-methylphenyl)-N,N′-bis-(phenyl)-benzidine), and MTDATA(4,4′,4-Tris(N-3-methylphenyl-N-phenyl-amino)-triphenylamine), or a combination thereof, although the embodiment is not limited thereto.

In an embodiment, the first emission part EU1 may include the first lower emission layer 222L-1, the second lower emission layer 222L-2, and the third lower emission layer 222L-3, and further include a first common layer 221 and a second common layer 223. Specifically, the first common layer 221 may be disposed between the first pixel electrode 210-1 and the first lower emission layer 222L-1, between the second pixel electrode 210-2 and the second lower emission layer 222L-2, and between the third pixel electrode 210-3 and the third lower emission layer 222L-3. The second common layer 223 may be disposed between the first lower emission layer 222L-1 and the charge generation layer 224, between the second lower emission layer 222L-2 and the charge generation layer 224, and between the third lower emission layer 222L-3 and the charge generation layer 224. The first common layer 221 and the second common layer 223 may each be implemented as a structure on the first display element DPE1, the second display element DPE2, and the third display element DPE3.

In other words, the first emission part EU1 of the first pixel PX1 may include the first common layer 221, the first lower emission layer 222L-1, and the second common layer 223 sequentially stacked each other on the first pixel electrode 210-1. The first emission part EU1 of the second pixel PX2 may include the first common layer 221, the second lower emission layer 222L-2, and the second common layer 223 sequentially stacked each other on the second pixel electrode 210-2. The first emission part EU1 of the third pixel PX3 may include the first common layer 221, the third lower emission layer 222L-3, and the second common layer 223 sequentially stacked each other on the third pixel electrode 210-3. The first common layer 221 and the second common layer 223 may be common layers continuously formed on the first pixel PX1, the second pixel PX2, and the third pixel PX3.

The first common layer 221 may include a single layer or a multi-layer. As an example, in the case where the first common layer 221 includes a polymer material, the first common layer 221 may include a hole transport layer (HTL), which has a single-layered structure, and may include polyethylene dihydroxythiophene (PEDOT: poly-(3,4)-ethylene-dihydroxy thiophene) and/or polyaniline (PANI: polyaniline). In the case where the first common layer 221 includes a low molecular weight material, the first common layer 221 may include a hole injection layer (HIL) and an HTL. The second common layer 223 may be omitted. The second common layer 223 may include a single layer or a multi-layer. The second common layer 223 may include an electron transport layer (ETL) and/or an electron injection layer (EIL).

In an embodiment, the second emission part EU2 may include the first upper emission layer 222U-1, the second upper emission layer 222U-2, and the third upper emission layer 222U-3, and further include a third common layer 225 and a fourth common layer 227. Specifically, the third common layer 225 may be disposed between the charge generation layer 224 and the first upper emission layer 222U-1, between the charge generation layer 224 and the second upper emission layer 222U-2, and between the charge generation layer 224 and the third upper emission layer 222U-3. The fourth common layer 227 may be disposed between the first upper emission layer 222U-1 and the opposite electrode 230, between the second upper emission layer 222U-2 and the opposite electrode 230, and between the third upper emission layer 222U-3 and the opposite electrode 230. The third common layer 225 and the fourth common layer 227 may each be implemented as a structure on the first display element DPE1, the second display element DPE2, and the third display element DPE3.

In other words, the second emission part EU2 of the first pixel PX1 may include the third common layer 225, the first upper emission layer 222U-1, and the fourth common layer 227 sequentially stacked each other on the charge generation layer 224. The second emission part EU2 of the second pixel PX2 may include the third common layer 225, the second upper emission layer 222U-2, and the fourth common layer 227 sequentially stacked each other on the charge generation layer 224. The second emission part EU2 of the third pixel PX3 may include the third common layer 225, the third upper emission layer 222U-3, and the fourth common layer 227 sequentially stacked each other on the charge generation layer 224. The third common layer 225 and the fourth common layer 227 may be common layers continuously formed on the first pixel PX1, the second pixel PX2, and the third pixel PX3.

The third common layer 225 may include a single layer or a multi-layer. As an example, in the case where the third common layer 225 includes a polymer material, the third common layer 225 may include an HTL, which has a single-layered structure, and may include polyethylene dihydroxythiophene (PEDOT: poly-(3,4)-ethylene-dihydroxy thiophene) and/or polyaniline (PANI: polyaniline). In the case where the third common layer 225 includes a low molecular weight material, the third common layer 225 may include an HIL and an HTL. The fourth common layer 227 may be omitted. The fourth common layer 227 may include a single layer or a multi-layer. The fourth common layer 227 may include an ETL and/or an EIL.

Thicknesses of the first lower emission layer 222L-1 and the first upper emission layer 222U-1, thicknesses of the second lower emission layer 222L-2 and the second upper emission layer 222U-2, and thicknesses of the third lower emission layer 222L-3 and the third upper emission layer 222U-3 may be determined according to a resonance distance. An auxiliary layer (not shown) is a layer added to adjust the resonance distance and may include a resonance auxiliary material. As an example, the auxiliary layer and an HTL may include a same material. The auxiliary layer may be implemented as part of at least one of the first display element DPE1, the second display element DPE2, and/or the third display element DPE3 to adjust the resonance distance of each of the first pixel PX1, the second pixel PX2, and the third pixel PX3. As an example, the first display element DPE1 may include the auxiliary layer, and the auxiliary layer may be disposed on the first upper emission layer 222U-1.

In addition, the first display element DPE1, the second display element DPE2, and the third display element DPE3 may each further include a capping layer (not shown) disposed outside the opposite electrode 230. The capping layer may be configured to improve light emission efficiency based on the constructive interference principle. Accordingly, the light extraction efficiency of the first display element DPE1, the second display element DPE2, and the third display element DPE3 may increase, thereby improving the light emission efficiency of the first display element DPE1, the second display element DPE2, and the third display element DPE3.

As described above, the first display element DPE1, the second display element DPE2, and the third display element DPE3 of the display apparatus 1 according to an embodiment may each have a tandem structure including emission layers. Accordingly, the degree of lifetime improvement of the second pixel PX2 configured to emit blue light may be greater than the degree of lifetime of the first pixel PX1 configured to emit red light and the third pixel PX3 configured to emit green light.

Table 1 shows the lifetimes of the pixels including a single emission layer and the pixels including emission layers. Specifically, the lifetimes of the pixels were measured under a state in which other conditions are the same except for the number of emission layers implemented as part of the pixels. R represents a pixel configured to emit red light, B represents a pixel configured to emit blue light, and G represents a pixel configured to emit green light. An aperture ratio represents a relative area of an opening of each pixel. Specifically, as shown in FIG. 4, the pixel configured to emit red light and the pixel configured to emit green light may be disposed in the same column, and the pixel configured to emit blue light may be disposed in a column different from the column in which the pixel configured to emit red light and the pixel configured to emit green light are disposed. A size of each column may be the same, and the aperture ratio means a ratio of an area of the respective pixels in the column in which the pixels are disposed. For example, the aperture ratio may be a relative area among the pixels. The lifetime represents a drivable period in hours (h) when the same voltage is applied to each pixel.

In Experiment 1, a pixel configured to emit red light, a pixel configured to emit blue light, and a pixel configured to emit green light each include a single emission layer. In Experiment 2, a pixel configured to emit red light, a pixel configured to emit blue light, and a pixel configured to emit green light each include two emission layers. For example, Experiment 2 has a tandem structure.

TABLE 1

| Pixel | | R | B | G |
|---|---|---|---|---|
| Aperture ratio (%) | | 20.92 | 46.68 | 26.30 |
| lifetime (h) | Experiment 1 | 5800 | 2700 | 5200 |
| | Experiment 2 | 14200 | 10900 | 10300 |

Referring to Table 1, in the case where each pixel includes two emission layers, the lifetime of each pixel may improve compared to the case where each pixel includes a single emission layer. Specifically, a pixel configured to emit red light in Experiment 1 has a lifetime of about 5,800 hours, and a pixel configured to emit red light in Experiment 2 has a lifetime of about 14,200 hours. For example, in the case a pixel configured to emit red light includes two emission layers, the lifetime of the pixel configured to emit red light may increase by about 2.4 times compared to the case where a pixel configured to emit red light includes a single emission layer. Similarly, a pixel configured to emit green light in Experiment 1 has a lifetime of about 5200 hours, and a pixel configured to emit green light in Experiment 2 has a lifetime of about 10,300 hours. For example, in the case a pixel configured to emit green light includes two emission layers, the lifetime of the pixel configured to emit green light may increase by about 2.0 times compared to the case where a pixel configured to emit green light includes a single emission layer.

A pixel configured to emit blue light in Experiment 1 has a lifetime of about 2,700 hours, and a pixel configured to emit red light in Experiment 2 has a lifetime of about 10,900 hours. For example, in the case a pixel configured to emit blue light includes two emission layers, the lifetime of the pixel configured to emit blue light may increase by about 4.0 times compared to the case where a pixel configured to emit blue light includes a single emission layer. In other words, in the case where each pixel includes two emission layers, the degree of lifetime improvement of a pixel configured to emit blue light may be greater than the degree of lifetime improvement of a pixel configured to emit red light and a pixel configured to emit green light. The degree of lifetime improvement of a pixel configured to emit blue light may be based on a material of the emission layer of a pixel configured to emit blue light may be more suitable for a structure including emission layers than a structure including a single emission layer.

Accordingly, in the case where each pixel includes two emission layers, the area of the opening of the pixel configured to emit blue light may be smaller than the area of a conventional pixel having a single emission layer and configured to emit blue light. For example, in the case where each pixel includes two emission layers, an aperture ratio of the pixel configured to emit blue light may decrease. Specifically, in Experiment 2, an aperture ratio of the pixel configured to emit red light is about 20.92%, an aperture ratio of the pixel configured to emit blue light is about 46.68%, and an aperture ratio of the pixel configured to emit green light is about 26.30%. In the case of having a tandem structure as in Experiment 2, even though an aperture ratio of the pixel configured to emit red light is about 20.92%, an aperture ratio of the pixel configured to emit blue light is about 23.34%, and an aperture ratio of the pixel configured to emit green light is about 26.30%, the display apparatus including the pixels having the aperture ratios may be configured to properly display desired images.

Generally, in the case of the pixels having a single emission layer, a lifetime of the pixel configured to emit blue light is less than a lifetime of the pixel configured to emit red light and the pixel configured to emit green light. Accordingly, in the case of the pixels having a single emission layer, an aperture ratio of the pixel configured to emit blue light may be greater than aperture ratios of the pixel configured to emit red light and the pixel configured to emit green light.

However, each pixel PX according to an embodiment includes two emission layers. Accordingly, in an embodiment, an aperture ratio of the second pixel PX2 configured to emit blue light may decrease. Specifically, an aperture ratio of the second pixel PX2 configured to emit blue light may be less than an aperture ratio of the third pixel PX3 configured to emit green light. For example, the area of the second opening OP2 may be less than the area of the third opening OP3. In other words, the area of the second emission area EA2 may be less than the area of the third emission area EA3.

Table 2 shows lifetime of the pixels having the emission layers. Specifically, in Experiment 3, the pixel configured to emit red light, the pixel configured to emit blue light, and the pixel configured to emit green light each have two emission layers. For example, Experiment 3 shows a tandem structure, and lifetime of each pixel in Experiment 3 was measured. Some of other conditions except for the number of emission layers implemented as part of the pixels may be different in Experiment 3 compared to Experiment 2. Expected lifetime represents expected lifetime of each pixel in the case where a pixel configured to emit red light, a pixel configured to emit blue light, and a pixel configured to emit green light each include two emission layers, compared to the case where a pixel configured to emit red light, a pixel configured to emit blue light, and a pixel configured to emit green light each include a single emission layer. The above descriptions made to R, B, G, an aperture ratio, and lifetime are equally applicable to Table 2, hence repeated descriptions are omitted.

TABLE 2

| | | | |
|---|---|---|---|
| Pixel | R | B | G |

| Aperture ratio (%) | | 21.85 | 64.86 | 45.97 |
|---|---|---|---|---|
| Lifetime (h) | Expected | 4000 | 2400 | 4000 |
| | lifetime | | | |
| | Experiment 3 | 4700 | 5100 | 4000 |

Referring to Table 2, in the case where the pixel configured to emit red light includes two emission layers, expected lifetime of the pixel configured to emit red light is about 4000 hours. In Experiment 3, the pixel configured to emit red light has lifetime of about 4700 hours, which is similar to the expected lifetime. In the case where the pixel configured to emit green light includes two emission layers, the expected lifetime of the pixel configured to emit green light is about 4000 hours. In Experiment 3, the pixel configured to emit green light has a lifetime of about 4000 hours, which is the same as the expected lifetime.

However, in the case where the pixel configured to emit blue light includes two emission layers, the expected lifetime of the pixel configured to emit blue light is about 2400 hours. In Experiment 3, the pixel configured to emit blue light has a lifetime of about 5100 hours, which is about 2.1 times greater than the expected lifetime. For example, as described above, in the case where each pixel includes two emission layers, the degree of lifetime improvement of a pixel configured to emit blue light may be greater than the degree of lifetime improvement of a pixel configured to emit red light and a pixel configured to emit green light. The degree of lifetime improvement may be based on a material of the emission layer of a pixel configured to emit blue light may be more suitable for a structure including a plurality of emission layers than a structure including a single emission layer.

Accordingly, in the case where each pixel includes two emission layers, even though an aperture ratio of the pixel configured to emit blue light is less than an aperture ratio of a conventional pixel having a single emission layer and configured to emit blue light, the display apparatus including the pixels having the reduced aperture ratio may be configured to display desired images properly. Specifically, in the case of having a tandem structure as in Experiment 3, even though the aperture ratio of the pixel configured to emit blue light is reduced to about ½ of 64.86%, the display apparatus including the pixels having the reduced aperture ratio may be configured to display desired images properly.

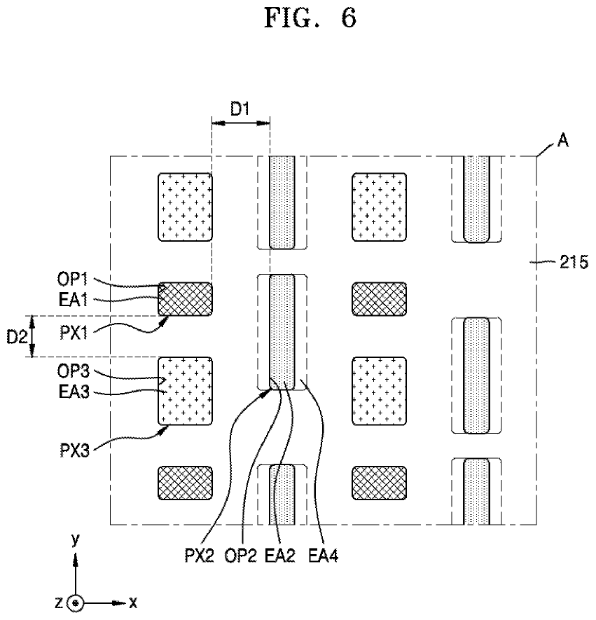

FIG. 6 is a view illustrating a size of an area of the second opening OP2 of the display apparatus 1 according to an embodiment. FIG. 6 illustrates that, in the case of having a single emission layer, a fourth emission area EA4 of the pixel (hereinafter, referred to as a blue pixel having a single emission layer) configured to emit blue light may overlap and face the second emission area EA2 in a plan view as indicated by a dashed line.

As shown in FIG. 6, the blue pixel having a single emission layer may have the fourth emission area EA4 of a greater area than an area of the second emission area EA2 of the second pixel PX2. In the case of having a single emission layer, an emission area of a pixel (hereinafter, a red pixel having a single emission layer) configured to emit red light may be the same as or similar to the first emission area EA1 of the first pixel PX1 in size and position in a plan view. In the case of having a single emission layer, an emission area of a pixel (hereinafter, a green pixel having a single emission layer) configured to emit green light may be the same as or similar to the third emission area EA3 of the third pixel PX3 in size and position in a plan view. Accordingly, the fourth emission area EA4 may be greater than the third emission area EA3, and a distance between a red pixel of a single emission layer and a blue pixel of a single emission layer may be the same as or similar to a distance between a red pixel of a single emission layer and a green pixel of a single emission layer.

However, as described with reference to Table 1, in the case where each pixel includes two emission layers, the area of the opening of the pixel configured to emit blue light may be less than the area of the opening of the pixel having a single emission layer and configured to emit blue light. Accordingly, as shown in FIG. 6, the area of the second emission area EA2 may be less than the area of the fourth emission area EA4 of the blue pixel of a single emission layer. Accordingly, the area of the second emission area EA2 may be less than the area of the third emission area EA3. In other words, the area of the second opening OP2 may be less than the area of the third opening OP3.

Accordingly, a first distance D1 between the first pixel PX1 and the second pixel PX2 may be greater than a second distance D2 between the first pixel PX1 and the third pixel PX3. As described above, the area of the second emission area EA2 may be less than the area of the fourth emission area EA4, as shown in FIG. 6, hence the width in the first direction (e.g., the x direction or the opposite −x direction) of the second emission area EA2 may be less than the width in the first direction (e.g., the x direction or the opposite −x direction) of the fourth emission area EA4. The first emission area EA1 of the first pixel PX1 may be adjacent to the second emission area EA2 of the second pixel PX2 in the first direction (e.g., the x direction or the opposite −x direction), and the width in the first direction (e.g., the x direction or the opposite −x direction) of the second emission area EA2 may be less than the width in the first direction (e.g., the x direction or the opposite −x direction) of the fourth emission area EA4. Accordingly, the first distance D1 between the first pixel PX1 and the second pixel PX2 may be greater than the second distance D2 between the first pixel PX1 and the third pixel PX3. For example, a distance between the first opening OP1 and the second opening OP2 may be greater than a distance between the first opening OP1 and the third opening OP3. In other words, a distance between the first pixel EA1 and the second pixel EA2 may be a distance between the first emission area EA1 and the third emission area EA3.

In the case where there are layers implemented as single structures on the display elements DPE, a leakage current may flow between the display elements DPE through the layers. As an example, the first common layer 221, the second common layer 223, the third common layer 225, and the fourth common layer 227 may be implemented as single structures on the first display element DPE1, the second display element DPE2, and the third display element DPE3. Accordingly, a leakage current may flow between the first display element DPE1, the second display element DPE2, and the third display element DPE3 through the layers. Specifically, even in the case where a current is supplied to only the second display element DPE2 configured to emit blue light, a leakage current may be supplied to even the first display element DPE1 through the first common layer 221. As another example, a current may be supplied to the first display element DPE1 through the second common layer 223, a current may be supplied to the first display element DPE1 through the third common layer 225, or a current may be supplied to the first display element DPE1 through the fourth common layer 227.

A driving current of the first display element DPE1 configured to emit red light may be smaller than a driving current of the second display element DPE2 configured to emit blue light. Accordingly, even though a small amount of current may be supplied due to a leakage current, not only green light may be emitted by the second display element DPE2 but also red light may be emitted by the first display element DPE1. Accordingly, a deterioration in display quality such as a deterioration in color purity may occur.

However, in the display apparatus 1 according to an embodiment, the first distance D1 between the first pixel PX1 and the second pixel PX2 may be relatively long. Specifically, the first distance D1 between the first pixel PX1 and the second pixel PX2 may be greater than the second distance D2 between the first pixel PX1 and the third pixel PX3. Accordingly, the amount of leakage current flowing between the first display element DPE1 and the second display element DPE2 through the first common layer 221, the second common layer 223, and the third common layer 225, may be small or may be nonexistent. Accordingly, in the case where the current is to be supplied to only the second display element DPE2, a current less than the driving current of the first display element DPE1 may be supplied to the first display element DPE1 or no current may be supplied to the first display element DPE1. Accordingly, display quality of the display apparatus 1 according to an embodiment may be maintained, such that the display quality does not deteriorate.

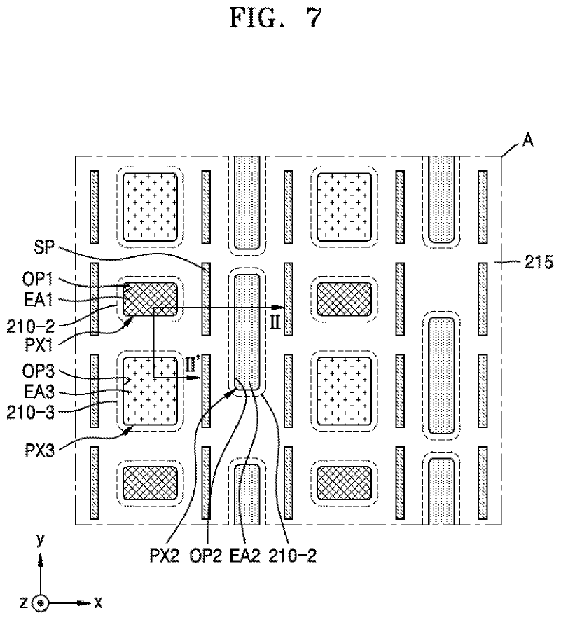

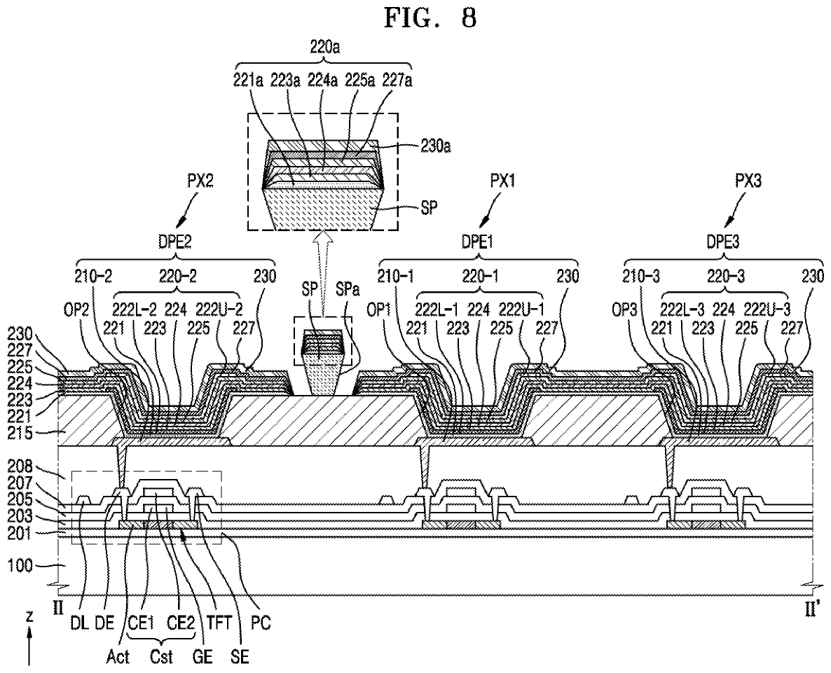

FIG. 7 is a schematic plan view of a portion of the display apparatus 1 according to an embodiment, and FIG. 8 is a schematic cross-sectional view of a portion of the display apparatus 1 according to an embodiment. Specifically, FIG. 8 is a schematic cross-sectional view of the display apparatus 1, taken along line II-IT of FIG. 7. For convenience of description, FIG. 7 shows a plan view of the pixel-defining layer 215. However, for convenience of description, a separator SP disposed on the pixel-defining layer 215 is shown together. The display apparatus 1 according to an embodiment may include the elements of the display apparatus 1 described above with reference to FIGS. 1 to 6 and may further include the separator SP.

As shown in FIGS. 7 and 8, the separator SP may be disposed on the pixel-defining layer 215. Specifically, as shown in FIG. 7, the separator SP may be disposed to correspond to a region between the second pixel PX2 and another pixel PX other than the second pixel PX2. As an example, in a plan view, the separator SP may be disposed between the second pixel PX2 and the first pixel PX1, or between the second pixel PX2 and the third pixel PX3. For example, in a plan view, the separator SP may be disposed between the second opening OP2 and the first opening OP1, or between the second opening OP2 and the third opening OP3. In other words, in a plan view, the separator SP may be disposed between the second emission area EA2 and the first emission area EA1, or between the second emission area EA2 and the third emission area EA3.

A first remaining intermediate layer 220a and a first remaining opposite electrode 230a may be disposed on the separator SP. Specifically, the first remaining intermediate layer 220a may be disposed on the separator SP, and the first remaining opposite electrode 230a may be disposed on the first remaining intermediate layer 220a. As shown in FIG. 8, the first remaining intermediate layer 220a may include a (1-1)st remaining common layer 221a, a (2-1)st remaining common layer 223a, a first remaining charge generation layer 224a, a (3-1)st remaining common layer 225a, and a (4-1)st remaining common layer 227a.

The (1-1)st remaining common layer 221a and the first common layer 221 may include a same material and may be simultaneously formed during the same process. Specifically, when a material forming the first common layer 221 is deposited on the entire surface of the substrate 100, a layer formed on the separator SP may be the (1-1)st remaining common layer 221a. The above description of the relationship between the (1-1)st remaining common layer 221a and the first common layer 221 is applicable to the relationship between the (2-1)st remaining common layer 223a and the second common layer 223, the relationship between the first remaining charge generation layer 224a and the charge generation layer 224, the relationship between the (3-1)st remaining common layer 225a and the third common layer 225, the relationship between the (4-1)st remaining common layer 227a and the fourth common layer 227, and the relationship between the first opposite electrode 230a and the opposite electrode 230; hence, repeated descriptions thereof are omitted.

The separator SP may include an organic insulating material. As an example, the separator SP may include photoresist, benzocyclobutene (BCB), polyimide, hexamethyldisiloxane (HMDSO), polymethylmethacrylate (PMMA), polystyrene, polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, or a compound thereof, or a combination thereof.

A lateral surface SPa of the separator SP may include a reverse-tapered slope surface. In case that the lateral surface SPa of the separator SP includes a reverse-tapered slope surface, the width of the portion of the separator SP in a direction (a +z direction) opposite to the substrate 100 may be greater than the width of the portion of the separator SP in a direction (a −z direction) of the substrate 100. The lateral surface SPa of the separator SP includes the reverse-tapered slope surface; hence, the (1-1)st remaining common layer 221a, the (2-1)st remaining common layer 223a, the first remaining charge generation layer 224a, the (3-1)st remaining common layer 225a, and the (4-1)st remaining common layer 227a on the separator SP may be respectively disconnected from the first common layer 221, the second common layer 223, the charge generation layer 224, the third common layer 225, and the fourth common layer 227.

Accordingly, the first common layer 221 of the second pixel PX2 may be partially disconnected from the first common layer 221 of the first pixel PX1. The second common layer 223 of the second pixel PX2 may be partially disconnected from the second common layer 223 of the first pixel PX1, and the charge generation layer 224 of the second pixel PX2 may be partially disconnected from the charge generation layer 224 of the first pixel PX1. The third common layer 225 of the second pixel PX2 may be partially disconnected from the third common layer 225 of the first pixel PX1, and the fourth common layer 227 of the second pixel PX2 may be partially disconnected from the fourth common layer 227 of the first pixel PX1. Accordingly, the amount of leakage current flowing between the first display element DPE1 and the second display element DPE2 through the first common layer 221, the second common layer 223, the charge generation layer 224, the third common layer 225, or the fourth common layer 227, may be reduced or eliminated, resulting in zero leakage current.

In addition, the first common layer 221, the second common layer 223, the charge generation layer 224, the third common layer 225, and the fourth common layer 227 of the second pixel PX2 may be respectively disconnected from the first common layer 221, the second common layer 223, the charge generation layer 224, the third common layer 225, and the fourth common layer 227 of the third pixel PX3; hence, the amount of leakage current flowing between the second display element DPE2 and the third display element DPE3 through the first common layer 221, the second common layer 223, the charge generation layer 224, the third common layer 225, or the fourth common layer 227, may be reduced or eliminated, resulting in zero leakage current.

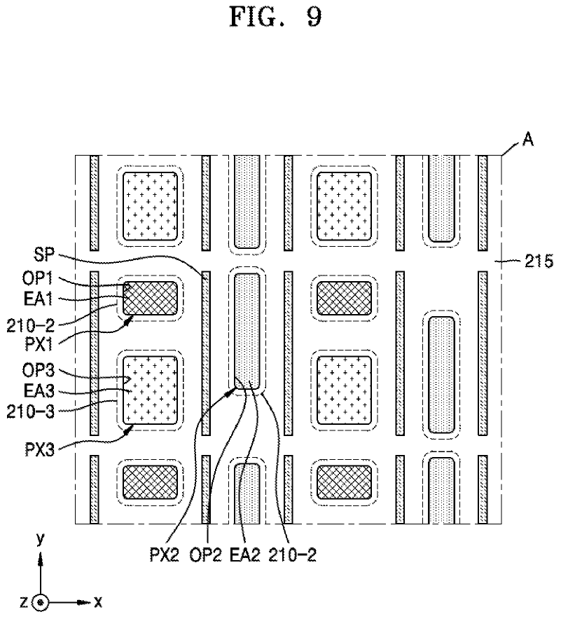

FIG. 7 illustrates that the separator SP between the second pixel PX2 and the first pixel PX1 is apart from the separator SP between the second pixel PX2 and the third pixel PX3, however the embodiment is not limited thereto. As an example, the separator SP may extend along a side of the second pixel PX2. In other words, the separator SP may extend along a side of the second opening OP2. For example, FIG. 9 illustrates a schematic plan view of a portion of the display apparatus 1 according to an embodiment, where the separator SP may extend in the second direction (e.g., the y direction or the opposite −y direction) along a side of the second opening OP2.

Accordingly, the separator SP (between the second pixel PX2 and the first pixel PX1) and the separator SP (between the second pixel PX2 and the third pixel PX3) may be integral with each other. For example, the separator SP between the second pixel PX2 and the first pixel PX1 may be connected to the separator SP between the second pixel PX2 and the third pixel PX3. In other words, in a plan view, a portion of the separator SP may be disposed between the second opening OP2 and the first opening OP1, and another portion of the separator SP may be disposed between the second opening OP2 and the third opening OP3.

FIG. 9 illustrates a plan view of the pixel-defining layer 215 where the separator SP may be disposed on the pixel-defining layer 215.

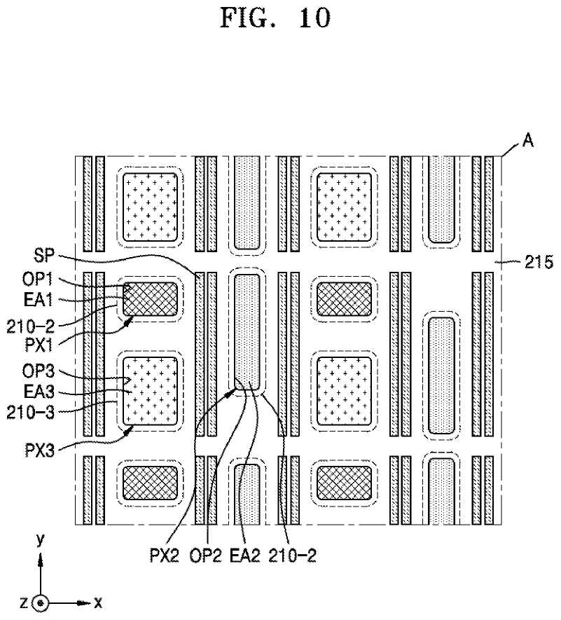

Although FIGS. 7 to 9 illustrate that a separator SP is disposed between the first pixel PX1 and the second pixel PX2, the embodiment is not limited thereto. As an example, in a plan view, separators SP may be disposed between the first opening OP1 and the second opening OP2. For example, FIG. 10 illustrates a schematic plan view of a portion of the display apparatus 1 according to an embodiment, where two separators SP may be disposed between the first opening OP1 and the second opening OP2. The separators SP may be spaced apart from each other. For example, the separators SP may be spaced apart from each other in the first direction (e.g., the x direction or the opposite −x direction).

As described above with reference to FIGS. 3 and 4, the area of the second opening OP2 may be small and the first distance D1 may be long; hence, the separators SP may be disposed on the pixel-defining layer 215 between the first opening OP1 and the second opening OP2. FIG. 10 illustrates a plan view of the pixel-defining layer 215 where the separator SP may be disposed on the pixel-defining layer 215.

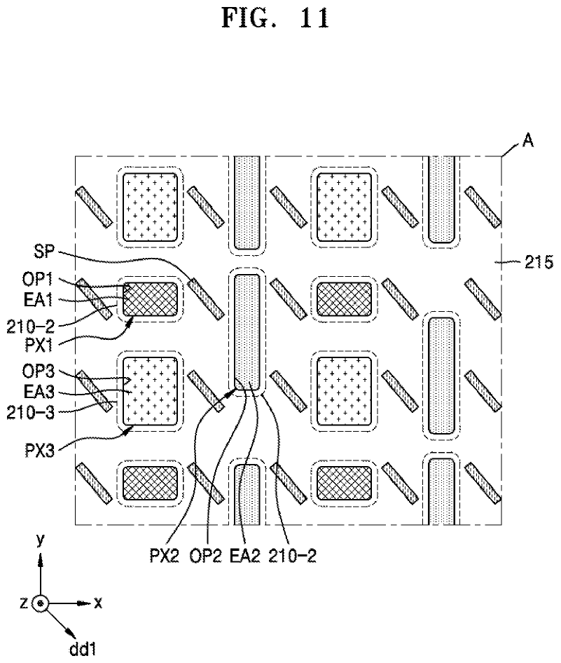

FIGS. 7 to 10 illustrate that the separator SP extends in the second direction (e.g., the y direction or the opposite −y direction), although the embodiment is not limited thereto. For example, FIG. 11 illustrates a schematic plan view of a portion of the display apparatus 1 according to an embodiment, where the separator SP may extend in a third direction (e.g., a direction between the +x direction and the −y direction, for example, a direction dd1). FIG. 11 illustrates a plan view of the pixel-defining layer 215 where the separator SP may be disposed on the pixel-defining layer 215.

As illustrated in FIG. 11, the first common layer 221, the second common layer 223, the charge generation layer 224, the third common layer 225, and the fourth common layer 227 of the second pixel PX2 may be respectively disconnected from the first common layer 221, the second common layer 223, the charge generation layer 224, the third common layer 225, and the fourth common layer 227 of the first pixel PX1. Accordingly, the amount of leakage current flowing between the first display element DPE1 and the second display element DPE2 through the first common layer 221, the second common layer 223, the charge generation layer 224, the third common layer 225, or the fourth common layer 227 may be reduced or eliminated, resulting in zero leakage current.

FIGS. 7 to 11 illustrate that the display apparatus 1 may further include the separator SP, although the embodiment is not limited thereto. For example, the display apparatus 1 may not include the separator SP and may include a pixel-defining layer groove 215G.

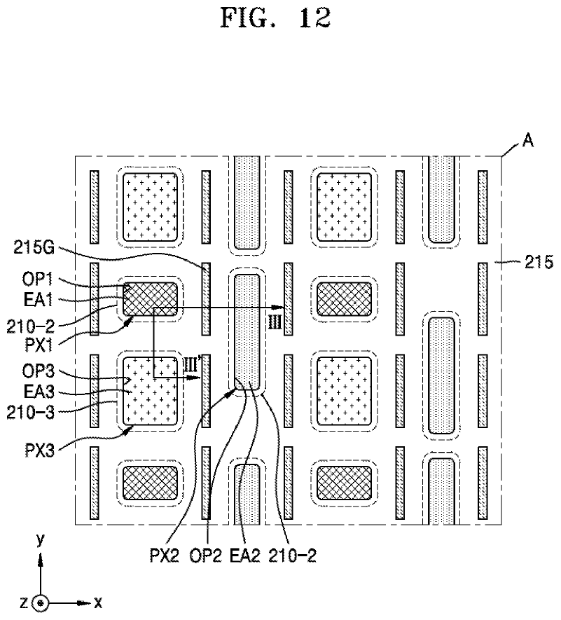

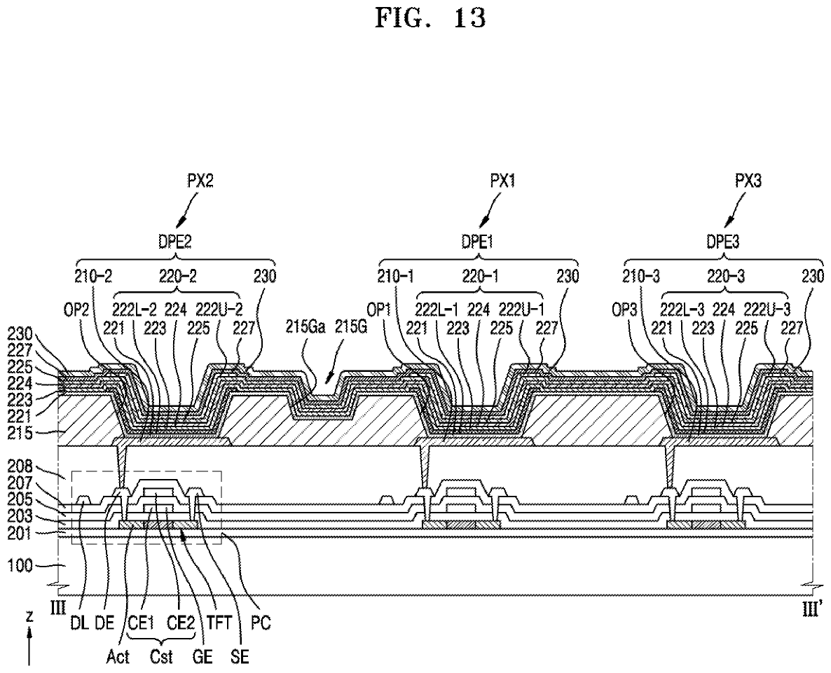

FIG. 12 is a schematic plan view of a portion of the display apparatus 1 according to an embodiment, and FIG. 13 is a schematic cross-sectional view of a portion of the display apparatus 1 according to an embodiment. Specifically, FIG. 13 is a schematic cross-sectional view of the display apparatus 1, taken along line III-III′ of FIG. 12. For convenience of description, FIG. 12 shows a plan view of the pixel-defining layer 215. The display apparatus 1 according to an embodiment may include the elements of the display apparatus 1 described above with reference to FIGS. 1 to 6 and may further include the pixel-defining layer groove 215G.

As shown in FIGS. 12 and 13, the pixel-defining layer groove 215G may be disposed in the upper surface (in a +z direction) of the pixel-defining layer 215. Specifically, as shown in FIG. 12, the pixel-defining layer groove 215G may be disposed to correspond to a region between the second pixel PX2 and another pixel PX other than the second pixel PX2. As an example, in a plan view, the pixel-defining layer groove 215G may be disposed between the second pixel PX2 and the first pixel PX1, or between the second pixel PX2 and the third pixel PX3. For example, in a plan view, the pixel-defining layer groove 215G may be disposed between the second opening OP2 and the first opening OP1, or between the second opening OP2 and the third opening OP3. In other words, in a plan view, the pixel-defining layer groove 215G may be disposed between the second emission area EA2 and the first emission area EA1, or between the second emission area EA2 and the third emission area EA3.

As shown in FIG. 13, an inner surface 215Ga of the pixel-defining layer groove 215G may include a forward-tapered slope surface. In case that the lateral surface 215Ga of the pixel-defining layer groove 215G includes a reverse-tapered slope surface, the width of the portion of the pixel-defining layer groove 215G in the direction (the +z direction) opposite to the substrate 100 may be greater than the width of the portion of the pixel-defining layer groove 215G in the direction (the −z direction) of the substrate 100.

The first common layer 221, the second common layer 223, the charge generation layer 224, the third common layer 225, and the fourth common layer 227 may be disposed in the pixel-defining layer groove 215G. For example, unlike the (1-1)st remaining common layer 221a on the separator SP, the first common layer 221 disposed in the pixel-defining layer groove 215G may be electrically connected to the first common layer 221 implemented as part of the pixels PX. The second common layer 223, the charge generation layer 224, the third common layer 225, and the fourth common layer 227 disposed in the pixel-defining layer groove 215G may be respectively electrically connected to the second common layer 223, the charge generation layer 224, the third common layer 225, and the fourth common layer 227 provide to the pixels PX. The opposite electrode 230 disposed on the separator SP may be electrically connected to the opposite electrode 230 implemented as part of the pixels PX.

Accordingly, the first common layer 221 of the second pixel PX2 may be electrically connected to the first common layer 221 of the first pixel PX1. The second common layer 223 of the second pixel PX2 may be electrically connected to the second common layer 223 of the first pixel PX1, the third common layer 225 of the second pixel PX2 may be electrically connected to the third common layer 225 of the first pixel PX1, and the fourth common layer 227 of the second pixel PX2 may be electrically connected to the fourth common layer 227 of the first pixel PX1.

However, the thickness of the first common layer 221 disposed on the inner surface 215Ga of the pixel-defining layer groove 215G may be less than the thickness of the first common layer 221 disposed on the upper surface (in the +z direction) of the pixel-defining layer 215 except for the inner surface 215Ga. In addition, the thickness of the second common layer 223 disposed on the inner surface 215Ga may be less than the thickness of the second common layer 223 disposed on the upper surface (in the +z direction) of the pixel-defining layer 215 except for the inner surface 215Ga, the thickness of the third common layer 225 disposed on the inner surface 215Ga may be less than the thickness of the third common layer 225 disposed on the upper surface (in the +z direction) of the pixel-defining layer 215 except for the inner surface 215Ga, and the thickness of the fourth common layer 227 disposed on the inner surface 215Ga may be less than the thickness of the fourth common layer 227 disposed on the upper surface (in the +z direction) of the pixel-defining layer 215 except for the inner surface 215Ga. Accordingly, the amount of leakage current flowing between the first display element DPE1 and the second display element DPE2 through the first common layer 221, the second common layer 223, the third common layer 225, or the fourth common layer 227 may be reduced or eliminated, resulting in zero leakage current.

Descriptions of the connection between the separators SP and the extension direction and the number of the separator SP are applicable to the pixel-defining layer groove 215G, hence repeated descriptions thereof are omitted.

Specifically, in a plan view, pixel-defining layer grooves 215G may be disposed between the first opening OP1 and the second opening OP2. The pixel-defining layer groove 215G may extend along a side of the second opening OP2. Specifically, the pixel-defining layer groove 215G may extend in the second direction (e.g., the y direction or the opposite −y direction). Accordingly, in a plan view, a portion of the pixel-defining layer groove 215G may be disposed between the second opening OP2 and the first opening OP1, and another portion of the pixel-defining layer groove 215G may be disposed between the second opening OP2 and the third opening OP3. The pixel-defining layer groove 215G may extend in the third direction dd1.

FIGS. 7 to 13 illustrate that the display apparatus 1 may further include the separator SP or the pixel-defining layer groove 215G, although the embodiment is not limited thereto. As an example, the display apparatus 1 may not further include the separator SP or the pixel-defining layer groove 215G but may further include a spacer structure SPC.

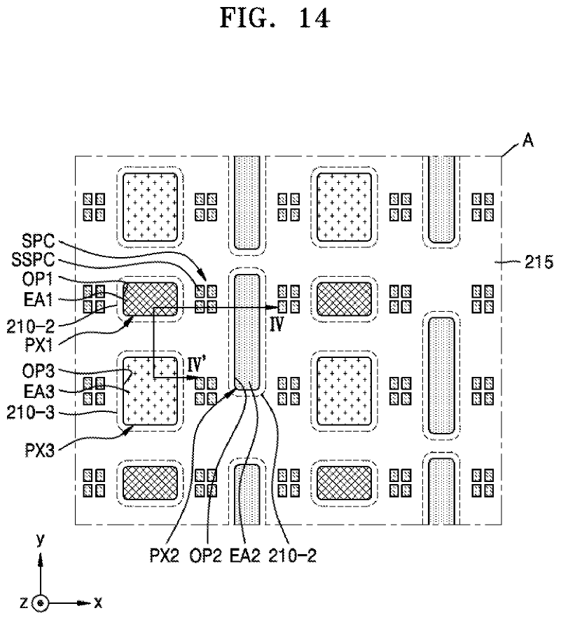

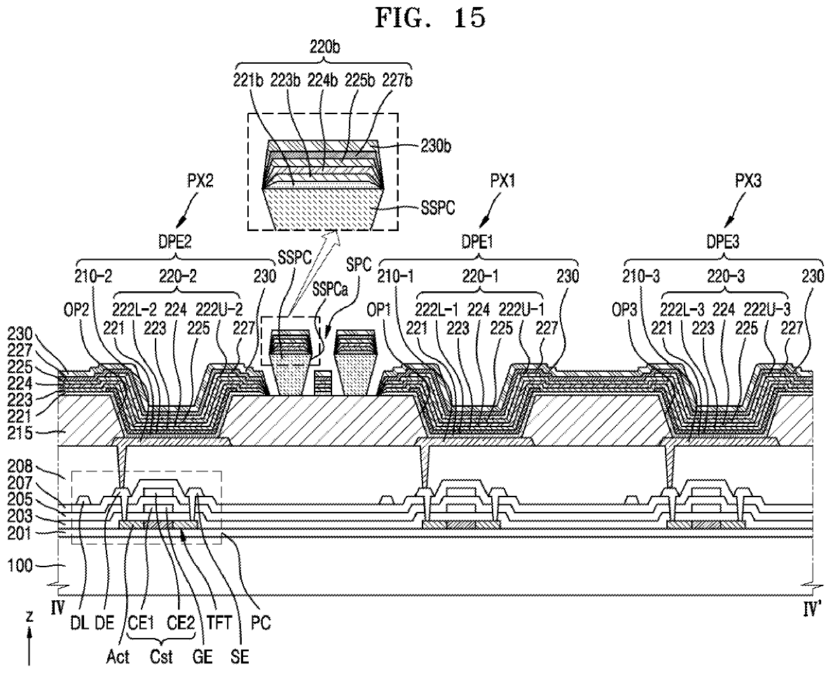

FIG. 14 is a schematic plan view of a portion of the display apparatus 1 according to an embodiment, and FIG. 15 is a schematic cross-sectional view of a portion of the display apparatus 1 according to an embodiment. Specifically, FIG. 15 is a schematic cross-sectional view of the display apparatus 1, taken along line IV-IV′ of FIG. 14. For convenience of description, FIG. 15 shows a plan view of the pixel-defining layer 215. However, for convenience of description, the spacer structure SPC disposed on the pixel-defining layer 215 is shown together. The display apparatus 1 according to an embodiment may include the elements of the display apparatus 1 described above with reference to FIGS. 1 to 6 and may further include the spacer structure SPC.

As shown in FIGS. 14 and 15, the spacer structure SPC may be disposed on the pixel-defining layer 215. Specifically, as shown in FIG. 14, the spacer structure SPC may be disposed to correspond to a region between the second pixel PX2 and another pixel PX other than the second pixel PX2. As an example, in a plan view, the spacer structure SPC may be disposed between the second pixel PX2 and the first pixel PX1, or between the second pixel PX2 and the third pixel PX3. For example, in a plan view, the spacer structure SPC may be disposed between the second opening OP2 and the first opening OP1, or between the second opening OP2 and the third opening OP3. In other words, in a plan view, the spacer structure SPC may be disposed between the second emission area EA2 and the first emission area EA1, or between the second emission area EA2 and the third emission area EA3.

A second remaining intermediate layer 220b and a second remaining opposite electrode 230b may be disposed on the spacer structure SPC. Specifically, the second remaining intermediate layer 220b may be disposed on the spacer structure SPC, and the second remaining opposite electrode 230b may be disposed on the second remaining intermediate layer 220b. As shown in FIG. 15, the second remaining intermediate layer 220b may include a (1-2)nd remaining common layer 221b, a (2-2)nd remaining common layer 223b, a second remaining charge generation layer 224b, a (3-2)nd remaining common layer 225b, and/or a (4-2)nd remaining common layer 227b.

The (1-2)nd remaining common layer 221b and the first common layer 221 may include a same material and may be simultaneously formed during the same process. Specifically, as a material forming the first common layer 221 is deposited on the entire surface of the substrate 100, a layer formed on the spacer structure SPC may be the (1-2)nd remaining common layer 221b. The above description of the relationship between the (1-2)nd remaining common layer 221b and the first common layer 221 is applicable to the relationship between the (2-2)nd remaining common layer 223b and the second common layer 223, the relationship between the second remaining charge generation layer 224b and the charge generation layer 224, the relationship between the (3-2)nd remaining common layer 225b and the third common layer 225, the relationship between the (4-2)nd remaining common layer 227b and the fourth common layer 227, and the relationship between the second opposite electrode 230b and the opposite electrode 230, hence repeated descriptions thereof are omitted.

The spacer structure SPC and the separator SP may include a same material. As an example, the separator SP may include photoresist, benzocyclobutene (BCB), polyimide, hexamethyldisiloxane (HMDSO), polymethylmethacrylate (PMMA), polystyrene, polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, or a compound thereof, or a combination thereof.

The spacer structure SPC may include four sub-spacers SSPC each including a square shape having equal or similar horizontal and vertical lengths. The sub-spacers SSPC may be spaced apart from each other in the first direction (e.g., the x direction or the opposite −x direction) and/or the second direction (e.g., the y direction or the opposite −y direction). For example, the spacer structure SPC may have a EH shape (in the shape of a 2×2 matrix grid). A lateral surface SSPCa of the sub-spacer SSPC may include a reverse-tapered slope surface. In case that the lateral surface SSPCa of the sub-spacer SSPC includes a reverse-tapered slope surface, the width of the portion of the sub-spacer SSPC in a direction (the +z direction) opposite to the substrate 100 may be greater than the width of the portion of the sub-spacer SSPC in a direction (the −z direction) of the substrate 100. The lateral surface SSPCa of the sub-spacer SSPC includes the reverse-tapered slope surface, hence the (1-2)nd remaining common layer 221b, the (2-2)nd remaining common layer 223b, the second remaining charge generation layer 224b, the (3-2)nd remaining common layer 225b, and the (4-2)nd remaining common layer 227b on the spacer structure SPC may be respectively disconnected from the first common layer 221, the second common layer 223, the charge generation layer 224, the third common layer 225, and the fourth common layer 227.

Accordingly, the first common layer 221 of the second pixel PX2 may be partially disconnected from the first common layer 221 of the first pixel PX1. The second common layer 223 of the second pixel PX2 may be partially disconnected from the second common layer 223 of the first pixel PX1, and the charge generation layer 224 of the second pixel PX2 may be partially disconnected from the charge generation layer 224 of the first pixel PX1. The third common layer 225 of the second pixel PX2 may be partially disconnected from the third common layer 225 of the first pixel PX1, and the fourth common layer 227 of the second pixel PX2 may be partially disconnected from the fourth common layer 227 of the first pixel PX1. Accordingly, the amount of leakage current flowing between the first display element DPE1 and the second display element DPE2 through the first common layer 221, the second common layer 223, the charge generation layer 224, the third common layer 225, or the fourth common layer 227 may be reduced or eliminated, resulting in zero leakage current.

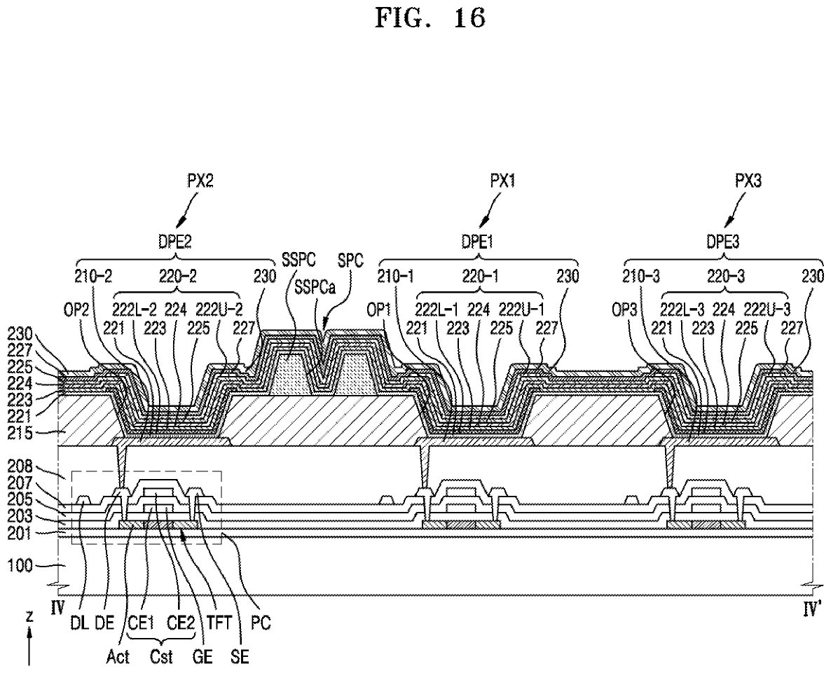

FIG. 15 illustrates that the lateral surface SSPCa of the sub-spacer SSPC has a reverse-tapered slope surface, although the embodiment is not limited thereto. As an example, as shown in FIG. 16 which is a schematic cross-sectional view of a portion of the display apparatus 1 according to an embodiment, the lateral surface SSPCa of the sub-spacer SSPC may have a forward-tapered slope surface. In case that the lateral surface SSPCa of the sub-spacer SSPC includes a forward-tapered slope surface, the width of the portion of the sub-spacer SSPC in a direction (the +z direction) opposite to the substrate 100 may be less than the width of the portion of the sub-spacer SSPC in an opposite direction (the −z direction) of the substrate 100.

The first common layer 221, the second common layer 223, the charge generation layer 224, the third common layer 225, and the fourth common layer 227 may be disposed on the spacer structure SPC. For example, the first common layer 221, the second common layer 223, the charge generation layer 224, the third common layer 225, and the fourth common layer 227 may cover the spacer structure SPC. Specifically, the first common layer 221, the second common layer 223, the charge generation layer 224, the third common layer 225, and the fourth common layer 227 may each cover the lateral surface SSPCa of the sub-spacer SSPC. In addition, the opposite electrode 230 may cover the lateral surface SSPCa of the sub-spacer SSPC. Accordingly, the opposite electrode 230 has bending and the surface area of the opposite electrode 230 may increase. The opposite electrode 230 may increase adhesive force with a layer disposed on the opposite electrode 230.

An encapsulation layer (not shown) may cover and protect display elements DPE such as an organic light-emitting diode OLED that may be readily damaged by external moisture, oxygen, or the like. The encapsulation layer may include a first inorganic encapsulation layer and a second inorganic encapsulation layer, cover the display area DA, and extend to the outside of the display area DA. According to an embodiment, the lateral surface SSPCa of the sub-spacer SSPC in the display apparatus 1 may include a forward-tapered slope surface, enabling the opposite electrode 230 to undergo bending and enabling an increase in the surface area of the opposite electrode 230. The encapsulation layer may be disposed on the opposite electrode 230, enabling an increase in an adhesive force between the encapsulation layer and the opposite electrode 230.

Unlike the (1-2)nd remaining common layer 221b in the case where the lateral surface SSPCa of the sub-spacer SSPC includes a reverse-tapered slope surface, the first common layer 221 disposed on the spacer structure SPC may be electrically connected to the first common layer 221 of the pixels PX. The second common layer 223, the charge generation layer 224, the third common layer 225, and the fourth common layer 227 disposed on the spacer structure SPC may be respectively electrically connected to the second common layer 223, the charge generation layer 224, the third common layer 225, and the fourth common layer 227 provide to the pixels PX. The opposite electrode 230 disposed on the spacer structure SPC may be electrically connected to the opposite electrode 230 implemented as part of the pixels PX.

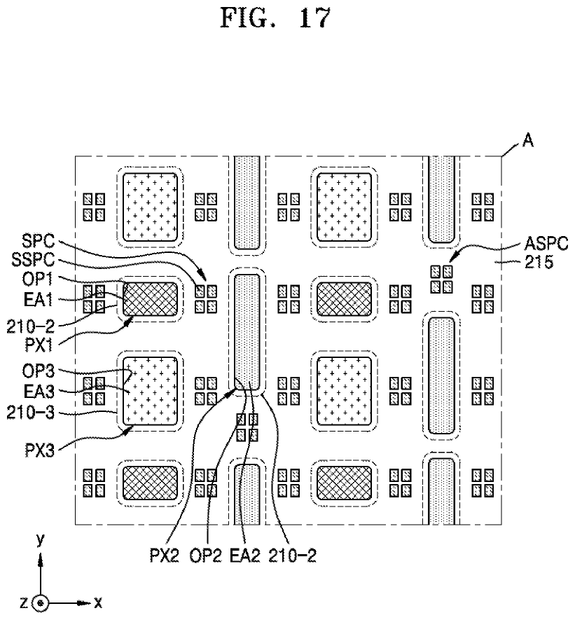

FIG. 17 is a schematic plan view of a portion of the display apparatus 1 according to an embodiment, where the display apparatus 1 may further include an auxiliary spacer structure ASPC. FIG. 17 illustrates a plan view of the pixel-defining layer 215, where the spacer structure SPC and the auxiliary spacer structure ASPC may be disposed on the pixel-defining layer 215. The auxiliary spacer structure ASPC is similar to the spacer structure SPC, enabling a description below of differences from the spacer structure SPC.

The spacer structure SPC may be disposed on the pixel-defining layer 215 and may include four sub-spacers SSPC each including a square shape having equal or similar horizontal and vertical lengths. The auxiliary spacer structure ASPC may be disposed on the pixel-defining layer 215 and may include four sub-spacers each including a square shape having equal or similar horizontal and vertical lengths.

However, the auxiliary spacer structure ASPC may be disposed in a region except for the region in which the spacer structure SPC is disposed. As an example, in a plan view, the auxiliary spacer structure ASPC may be disposed between the second pixels PX2 of the display apparatus 1. Specifically, in a plan view, the auxiliary spacer structure ASPC may be disposed between two second openings OP2. The descriptions of the spacer structure SPC except for the position of the spacer structure SPC in a plan view are applicable to the auxiliary spacer structure ASPC, hence repeated descriptions thereof are omitted.

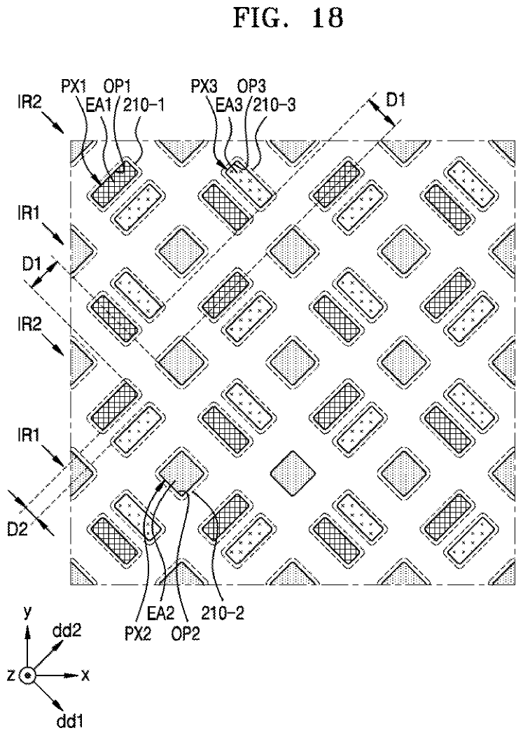

FIG. 18 is a schematic plan view of a display apparatus 1 according to an embodiment. FIG. 18 shows a plan view of the pixel-defining layer 215. In the display apparatus 1 according to an embodiment, the second pixels PX2 may be disposed at lattice points disposed with a constant interval in the first direction (e.g., the x direction or the opposite −x direction) and the second direction (e.g., the y direction or the opposite −y direction) perpendicular to the first direction (e.g., the x direction or the opposite −x direction). The first pixels PX1 and the third pixels PX3 may be disposed between the second pixels PX2 disposed as described above. Specifically, a pair of first pixel PX1 and third pixel PX3 may be disposed between two adjacent second pixels PX2.

As an example, in slope columns IR1 and IR2 extending in the third direction dd1 forming an angle of about 45° with respect to the first direction (e.g., the x direction or the opposite −x direction), a pair of first pixel PX1 and third pixel PX3 may be disposed between the second pixels PX2. The pair of first pixel PX1 and third pixel PX3 may extend in the third direction dd1 or a fourth direction dd2 approximately perpendicular to the third direction dd1. Specifically, first slope columns IR1 and second slope columns IR2 may be alternately disposed. A pair of first pixel PX1 and third pixel PX3 extending in the third direction dd1 may be located in the first slope column IR1. A pair of first pixel PX1 and third pixel PX3 extending in the fourth direction dd2 may be located in the second slope column IR2.

In this pixel configuration, the area of the second emission area EA2 of the second pixel PX2 may be less than the area of the third emission area EA3 of the third pixel PX3. Accordingly, the first distance D1 between the first pixel PX1 and the second pixel PX2 may be greater than the second distance D2 between the first pixel PX1 and the third pixel PX3. The second pixel PX2 according to an embodiment may be adjacent to the first pixel PX1 on four sides of the second pixel PX2, hence the second pixel PX2 according to an embodiment may have a square shape having equal or similar horizontal and vertical lengths as shown in FIG. 16.

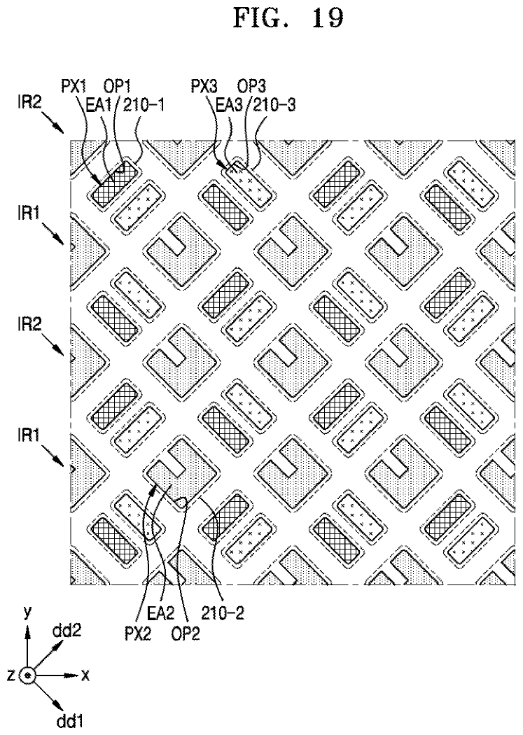

In the case where the area of the second emission area EA2 of the second pixel PX2 is not less than the area of the third emission area EA3 of the third pixel PX3, the second pixel PX2 may have a ‘U’ shape as shown in FIG. 19. FIG. 19 is a schematic plan view of a portion of the display apparatus according to a comparative example. FIG. 19 shows a plan view of the pixel-defining layer 215. The second pixel PX2 may include at least one organic layer. While the organic layer is formed, a gas may occur inside the organic layer, and the gas should be discharged to the outside of the organic layer. When the area of the second pixel PX2 is excessively large, the amount of gas occurring inside the organic layer during a process of forming the organic layer may be large, hence a vent hole may be formed to facilitate the discharging of the gas. Accordingly, the second pixel PX2 may have a ‘U’ shape.

However, the area of the second emission area EA2 of the second pixel PX2 of the display apparatus 1 according to an embodiment may be less than the area of the third emission area EA3 of the third pixel PX3. For example, if the amount of gas occurring inside the organic layer during the process of forming the organic layer is small, a vent hole may not be formed. Accordingly, the second pixel PX2 of the display apparatus 1 according to an embodiment may not have a ‘U’ shape, rather the second pixel PX2 of the display apparatus 1 according to an embodiment may have a square shape enabling an increase in a space utilization of the display area DA.

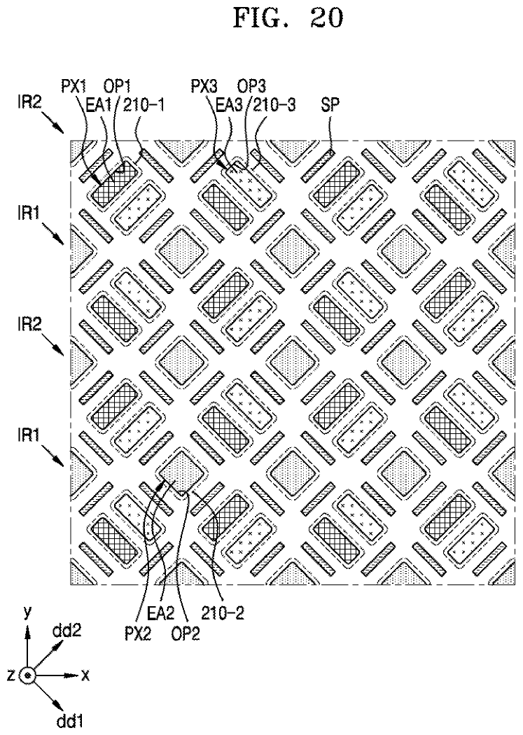

The separator SP may be disposed on the pixel-defining layer 215 in the pixel configuration described with reference to FIG. 18. FIG. 20 is a schematic plan view of a display apparatus 1 according to an embodiment, where the separator SP may be disposed to correspond to a region between the second pixel PX2 and another pixel PX other than the second pixel PX2. As an example, in a plan view, the separator SP may be disposed between the second pixel PX2 and the first pixel PX1, or between the second pixel PX2 and the third pixel PX3. FIG. 20 illustrates a plan view of the pixel-defining layer 215, where the separator SP may be disposed on the pixel-defining layer 215.

FIG. 3 and the like illustrate that the first pixel PX1, the second pixel PX2, and the third pixel PX3 may be disposed in a parallel stripe configuration, although the embodiment is not limited thereto. As an example, the first pixel PX1, the second pixel PX2, and the third pixel PX3 may be disposed in a diamond or a PenTile®-based configuration.

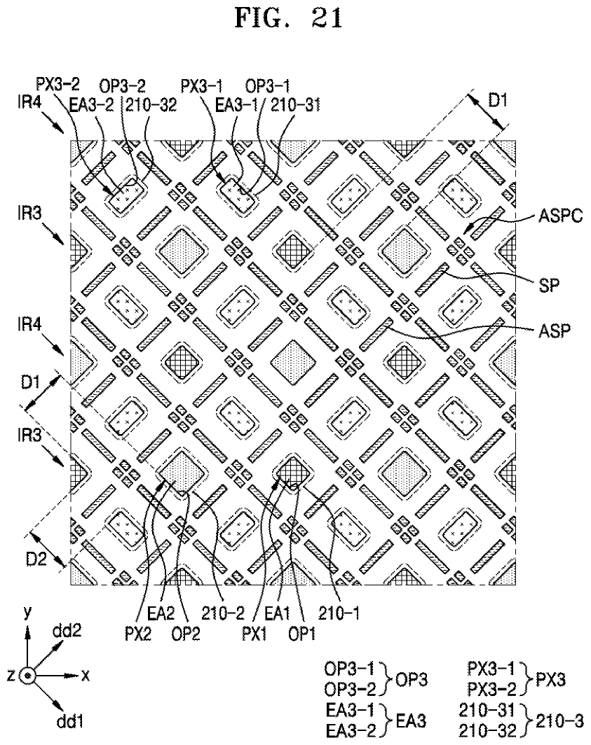

FIG. 21 is a schematic plan view of the display apparatus 1 according to an embodiment. FIG. 21 illustrates a plan view of the pixel-defining layer 215, where the separator SP, the auxiliary separator ASP, and the auxiliary spacer structure ASPC may be disposed on the pixel-defining layer 215.

In the display apparatus 1 according to an embodiment, the third pixel PX3 may include a (3-1)st sub-pixel PX3-1 and a (3-2)nd sub-pixel PX3-2. For example, the third pixel electrode 210-3 may include a (3-1)st sub-pixel electrode 210-31 and a (3-2)nd sub-pixel electrode 210-32, the third opening OP3 may include a (3-1)st sub-opening OP3-1 and a (3-2)nd sub-opening OP3-2, and the third emission area EA3 may include a (3-1)st sub-emission area EA3-1 and a (3-2)nd sub-emission area EA3-2.

The (3-1)st sub-emission area EA3-1 of the (3-1)st sub-pixel PX3-1 may extend in the third direction dd1, and the (3-2)nd sub-emission area EA3-2 of the (3-2)nd sub-pixel PX3-2 may extend in the fourth direction dd2. A plurality of (3-1)st sub-pixels PX3-1 and (3-1)st sub-pixels PX3-1 may be disposed at lattice points disposed with a constant interval in the first direction (e.g., the x direction or the opposite −x direction) and the second direction (e.g., the y direction or the opposite −y direction) perpendicular to the first direction (e.g., the x direction or the opposite −x direction). The first pixels PX1 and the second pixels PX2 may be disposed between the (3-1)st sub-pixels PX3-1 and the (3-2)nd sub-pixels PX3-2 disposed as described above.

As an example, in slope columns IR3 and IR4 extending in the third direction dd1, the first pixel PX1 and the second pixel PX2 may be disposed between the (3-1)st sub-pixels PX3-1 or the (3-2)nd sub-pixels PX3-2. In addition, the third slope columns IR3 in which the first pixels PX1 are disposed, and the fourth slope columns IR4 in which the second pixels PX2 are disposed may have a different arrangement or configuration. In each of the third slope columns IR3 in which the first pixels PX1 are disposed, the first pixel PX1 may be disposed between the adjacent (3-1)st sub-pixels PX3-1, and in each of the fourth slope columns IR4 in which the second pixels PX2 are disposed, the second pixel PX2 may be disposed between the adjacent (3-2)nd sub-pixels PX3-2.

In this pixel configuration, the area of the second emission area EA2 of the second pixel PX2 may be less than the area of the third emission area EA3 of the third pixel PX3. The third pixel PX3 may include the (3-1)st sub-pixel PX3-1 and the (3-2)nd sub-pixel PX3-2, hence the area of the third emission area EA3 may be a sum of the area of the (3-1)st sub-emission area EA3-1 and the area of the (3-2)nd sub-emission area EA3-2. For example, the area of the second emission area EA2 of the second pixel PX2 may be less than a sum of the area of the (3-1)st sub-emission area EA3-1 and the area of the (3-2)nd sub-emission area EA3-2.

Accordingly, a first distance D1 between the first pixel PX1 and the second pixel PX2 may be greater than a second distance D2 between the first pixel PX1 and the third pixel PX3. As described above, the first distance D1 between the first pixel PX1 and the second pixel PX2 means a distance between a side of the first pixel PX1 nearest the second pixel PX2, and a side of the second pixel PX2 nearest the first pixel PX1. As an example, the first distance D1 in the pixel configuration may be a distance in the third direction dd1 between a side in a +dd1 direction of the first emission area EA1 and a side in a −dd1 direction of the second emission area EA2. As another example, the first distance D1 may be a distance in the fourth direction dd2 between a side in the +dd2 direction of the first emission area EA1 and a side in the −dd2 direction of the second emission area EA2. The second pixel PX2 according to an embodiment may be adjacent to the first pixel PX1 on four sides of the second pixel PX2, hence the second pixel PX2 according to an embodiment may have a square shape having equal or similar horizontal and vertical lengths as shown in FIG. 16.

Even in the pixel configuration described with reference to FIG. 21, the separator SP may be disposed on the pixel-defining layer 215. As shown in FIG. 21, the separator SP may be disposed to correspond to a region between the second pixel PX2 and another pixel PX other than the second pixel PX2. As an example, in a plan view, the separator SP may be disposed between the second pixel PX2 and the third pixel PX3.

The pixel configuration described above with reference to FIG. 21 may further include the auxiliary separator ASP and the auxiliary spacer structure ASPC. The auxiliary separator ASP may be similar to the separator SP, hence differences from the separator SP are described below.

The separator SP may be disposed on the pixel-defining layer 215, and the auxiliary separator ASP may be also disposed on the pixel-defining layer 215. The auxiliary separator ASP may be disposed in a region other than a region in which the separator SP is disposed. As an example, in a plan view, the auxiliary separator ASP may be disposed between the first pixel PX1 and the third pixel PX3 of the display apparatus 1. Specifically, in a plan view, the auxiliary separator ASP may be disposed between the first pixel PX1 and the (3-1)st sub-pixel PX3-1 or disposed between the first pixel PX1 and the (3-2)nd sub-pixel PX3-2. In other words, in a plan view, the auxiliary separator ASP may be disposed between the first opening OP1 and the (3-1)st sub-opening OP3-1 or between the first opening OP1 and the (3-2)nd sub-opening OP3-2.

The descriptions of the separator SP except for the position of the separator SP on the pixel-defining layer 215 is applicable to the auxiliary separator ASP, hence repeated descriptions thereof are omitted.

The pixel configuration described above with reference to FIG. 21 may further include the auxiliary spacer structure ASPC. The auxiliary spacer structure ASPC may be disposed between the separators SP or between the separator SP and the auxiliary separator ASP. The auxiliary spacer structure ASPC according to an embodiment is different from the auxiliary spacer structure ASPC described with reference to FIG. 17 only in a position in a plan view. Accordingly, the descriptions of the spacer structure SPC except for the position in a plan view are applicable to the auxiliary spacer structure ASPC according to an embodiment, hence repeated descriptions thereof are omitted.

According to an embodiment, a display apparatus may effectively transfer electrical signals to opposite electrodes with a reduction in leakage current. However, the scope of the disclosure is not limited by this effect.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the following claims.

What is claimed is:

1. A display apparatus comprising:
a first pixel electrode, a second pixel electrode, and a third pixel electrode spaced apart from each other on a substrate;
a pixel-defining layer including a first opening, a second opening, and a third opening, wherein the first opening exposes a central portion of the first pixel electrode, the second opening exposes a central portion of the second pixel electrode, and the third opening exposes a central portion of the third pixel electrode;
a first lower emission layer disposed on the first pixel electrode and configured to emit red light;
a first upper emission layer disposed on the first lower emission layer and configured to emit red light;
a second lower emission layer disposed on the second pixel electrode and configured to emit blue light;
a second upper emission layer disposed on the second lower emission layer and configured to emit blue light;
a third lower emission layer disposed on the third pixel electrode and configured to emit green light;
a third upper emission layer disposed on the third lower emission layer and configured to emit green light;
a first common layer disposed between the first pixel electrode and the first lower emission layer, between the second pixel electrode and the second lower emission layer, and between the third pixel electrode and the third lower emission layer, and further disposed on the first pixel electrode, the second pixel electrode, and the third pixel electrode; and
an opposite electrode disposed on the first upper emission layer, the second upper emission layer, and the third upper emission layer, wherein
an area of the second opening is less than an area of the third opening; and
a first distance between the first opening and the second opening is greater than a second distance between the first opening and the third opening.

2. The display apparatus of claim 1, further comprising:
at least one separator disposed on the pixel-defining layer, the at least one separator disposed between:
the first opening and the second opening, or
the second opening and the third opening in a direction perpendicular to the substrate.

3. The display apparatus of claim 2, wherein
the at least one separator includes a plurality of separators, and
the plurality of separators are spaced apart from each other in the direction perpendicular to the substrate.

4. The display apparatus of claim 2, wherein the at least one separator includes a reverse-tapered slope surface.

5. The display apparatus of claim 2, wherein the at least one separator extends along a side of the second opening.

6. The display apparatus of claim 5, wherein a portion of the at least one separator is disposed between the second opening and the third opening in the direction perpendicular to the substrate.

7. The display apparatus of claim 2, further comprising:
a (1-1)st remaining common layer disposed on the at least one separator; and
a first remaining opposite electrode disposed on the (1-1)st remaining common layer.

8. The display apparatus of claim 7, wherein
the (1-1)st remaining common layer and the first common layer include a same material, and
the first remaining opposite electrode and the opposite electrode include a same material.

9. The display apparatus of claim 1, further comprising:
at least one pixel-defining layer groove disposed in an upper surface of the pixel-defining layer, the at least one pixel-defining layer groove disposed between the first opening and the second opening, or between the second opening and the third opening in a direction perpendicular to the substrate.

10. The display apparatus of claim 9, wherein
the at least one pixel-defining layer groove includes a plurality of pixel-defining layer grooves, and
the plurality of pixel-defining layer grooves are spaced apart from each other in the direction perpendicular to the substrate.

11. The display apparatus of claim 9, wherein the at least one pixel-defining layer groove includes a forward-tapered slope surface.

12. The display apparatus of claim 9, wherein the at least one pixel-defining layer groove extends along a side of the second opening.

13. The display apparatus of claim 12, wherein a portion of the at least one pixel-defining layer groove is disposed between the second opening and the third opening in the direction perpendicular to the substrate.

14. The display apparatus of claim 1, further comprising:
a spacer structure disposed on the pixel-defining layer, the spacer structure disposed between:
the first opening and the second opening, or
the second opening and the third opening in a direction perpendicular to the substrate;
wherein the spacer structure includes a plurality of sub-spacers.

15. The display apparatus of claim 14, wherein the plurality of sub-spacers are spaced apart from each other in the direction perpendicular to the substrate.

16. The display apparatus of claim 14, wherein the plurality of sub-spacers include reverse-tapered slope surfaces.

17. The display apparatus of claim 16, further comprising:
a (1-2)nd remaining common layer disposed on the spacer structure; and
a second remaining opposite electrode disposed on the (1-2)nd remaining common layer.

18. The display apparatus of claim 17, wherein
the (1-2)nd remaining common layer and the first common layer include a same material, and
the second remaining opposite electrode and the opposite electrode include a same material.

19. The display apparatus of claim 14, wherein the plurality of sub-spacers include forward-tapered slope surfaces.

20. The display apparatus of claim 1, further comprising:
a charge generation layer disposed between the first lower emission layer and the first upper emission layer, between the second lower emission layer and the second upper emission layer, and between the third lower emission layer and the third upper emission layer;
a second common layer disposed between the first lower emission layer and the charge generation layer, between the second lower emission layer and the charge generation layer, and between the third lower emission layer and the charge generation layer;
a third common layer disposed between the charge generation layer and the first upper emission layer, between the charge generation layer and the second upper emission layer, and between the charge generation layer and the third upper emission layer; and
a fourth common layer disposed between the first upper emission layer and the opposite electrode, between the second upper emission layer and the opposite electrode, and between the third upper emission layer and the opposite electrode.
